(19) United States
(12) Patent Application Publication
(10) Pub. No.: US 2026/0173984 A1
(43) Pub. Date: Jun. 18, 2026

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Changeun Joo, Suwon-si (KR); Jongyoun Kim, Suwon-si (KR); Sangkyu Lee, Suwon-si (KR)

(73) Assignee: Samsung Electronics Co., Ltd., Suwon-si (KR)

(21) Appl. No.: 19/421,448

(22) Filed: Dec. 16, 2025

(30) Foreign Application Priority Data
Dec. 18, 2024 (KR) 10-2024-0189370
Jun. 16, 2025 (KR) 10-2025-0079118

(51) Int. Cl. H10W 90/00; H10W 72/00; H10W 72/50; H10W 90/20; H10W 90/24

(52) U.S. Cl. CPC H10W 90/754; H10W 72/552; H10W 72/823; H10W 90/24; H10W 90/291

(57) ABSTRACT

A semiconductor package includes a redistribution wiring layer having redistribution wirings, a sealing member on the redistribution wiring layer and having a first surface in contact with the redistribution wiring layer and a second surface opposite the first surface, a plurality of semiconductor chips sequentially stacked on one another within the sealing member and arranged such that a front surface on which chip pads are formed faces the redistribution wiring layer, a bonding pad spaced apart from the chip pads on the front surface of the lowest semiconductor chip of the plurality of semiconductor chips that is closest to the first surface of the sealing member, first conductive wires extending substantially vertically from the first surface of the sealing member to the chip pads and electrically connected to the redistribution wirings, and second conductive wires extending substantially vertically from the first surface of the sealing member to the bonding pad.

### CROSS-REFERENCE TO RELATED APPLICATIONS

This present application claims priority to and the benefit under 35 U.S.C. § 119(a)-(d) of Korean Patent Application No. 10-2024-0189370, filed on Dec. 18, 2024, in the Korean Intellectual Property office, and of Korean Patent Application No. 10-2025-0079118, filed on Jun. 16, 2025, in the Korean Intellectual Property Office, the entire disclosures of which are incorporated herein by reference.

### FIELD

Example embodiments relate to a semiconductor package and a method of manufacturing the semiconductor package. More particularly, example embodiments relate to a multi-chip package including a plurality of stacked chips and a method of manufacturing the same.

### BACKGROUND

In manufacturing a fan-out package using vertical wires, the vertical wires may be formed on chip pads of sequentially stacked semiconductor chips by bonding wire processes, and a molding member may be formed by a molding process to cover the semiconductor chips and the vertical wires. As a wire diameter and pitch decrease, there is a problem that wire sagging occurs due to the flow of the molding material during the molding process, resulting in a wire short defect.

### SUMMARY

Example embodiments provide a semiconductor package having a structure that is able to prevent defects in a package manufacturing process.

According to example embodiments, a semiconductor package includes a redistribution wiring layer having redistribution wirings, a sealing member provided on the redistribution wiring layer and having a first surface in contact with the redistribution wiring layer and a second surface opposite to the first surface, a plurality of semiconductor chips sequentially stacked on one another within the sealing member and arranged such that a front surface on which chip pads of each of the semiconductor chips are formed faces the redistribution wiring layer, a bonding pad spaced apart from the chip pads on the front surface of the lowest semiconductor chip of the plurality of semiconductor chips that is closest to the first surface of the sealing member, first conductive wires extending substantially vertically from the first surface of the sealing member to the chip pads of the semiconductor chips and electrically connected to the redistribution wirings, respectively, and second conductive wires extending substantially vertically from the first surface of the sealing member to the bonding pad, respectively.

According to example embodiments, a semiconductor package includes a redistribution wiring layer having redistribution wirings, an encapsulation structure provided on the redistribution wiring layer, and outer connection members arranged on an outer surface of the redistribution wiring layer and electrically connected to the redistribution wirings. The encapsulation structure includes a sealing member having a first surface in contact with the redistribution wiring layer and a second surface opposite to the first surface; a plurality of semiconductor chips sequentially stacked within the sealing member such that a

front surface on which chip pads are formed faces the redistribution wiring layer, the lowest semiconductor chip of the plurality of semiconductor chips closest to the first surface of the sealing member having a bonding pad spaced apart from the chip pads; first conductive wires extending substantially vertically from the first surface of the sealing member to the chip pads of the semiconductor chips and electrically connected to the redistribution wirings, respectively; and second conductive wires extending substantially vertically from the first surface of the sealing member to the bonding pad of the lowest semiconductor chip, respectively. The bonding pad is provided on the front surface of the lowest semiconductor chip.

According to example embodiments, a semiconductor package includes a redistribution wiring layer having redistribution wirings, a sealing member provided on the redistribution wiring layer and having a first surface in contact with the redistribution wiring layer and a second surface opposite to the first surface, a plurality of semiconductor chips sequentially stacked on one another within the sealing member and arranged such that a front surface on which chip pads of each of the semiconductor chips are formed faces the redistribution wiring layer, a bonding pad spaced apart from the chip pads on the front surface of the lowest semiconductor chip of the plurality of semiconductor chips that is closest to the first surface of the sealing member, a connection wiring electrically connecting the bonding pad to at least one of the chip pads on the front surface of the lowest semiconductor chip, first conductive wires extending substantially vertically from the first surface of the sealing member to the chip pads of the semiconductor chips and electrically connected to the redistribution wirings, respectively, and second conductive wires extending substantially vertically from the first surface of the sealing member to the bonding pad, respectively. At least one of the second conductive wires is electrically connected to the redistribution wiring.

According to example embodiments, a semiconductor package may include a redistribution wiring layer and an encapsulation structure stacked on the redistribution wiring layer. The encapsulation structure may include a sealing member, a plurality of semiconductor chips arranged within the sealing member, first conductive wires extending substantially vertically from a first surface of the sealing member to chip pads of the semiconductor chips to be electrically connected to redistribution wirings of the redistribution wiring layer 100, and second conductive wires extending substantially vertically from the first surface of the sealing member to a bonding pad of the lowest semiconductor chip of the semiconductor chips.

After forming a plurality of bonding wires that connect the chip pads of the semiconductor chips and the bonding pad of the lowest semiconductor chip, the sealing member may be formed to cover the semiconductor chips and the plurality of bonding wires. Then, when removing an upper portion of the molding member, portions of the plurality of bonding wires may be removed together to simultaneously form the first conductive wires and the second conductive wires within the sealing member. Accordingly, after forming the vertical wires on the chip pads, the sealing process may be performed to form the sealing member, the phenomenon of the wires being tilted (wire sweep or wire sagging) due to a flow of a molding material during the sealing process may be prevented, to thereby prevent wire short defects.

### BRIEF DESCRIPTION OF THE DRAWINGS

Example embodiments will be more clearly understood from the following detailed description taken in conjunction with the accompanying drawings. FIGS. 1 to 29D represent non-limiting, example embodiments as described herein.

FIG. 1 is a cross-sectional view illustrating a semiconductor package in accordance with example embodiments.

FIG. 2 is an enlarged cross-sectional view illustrating portion ‘A’in FIG. 1.

FIG. 3 is a bottom view illustrating a sealing member of the semiconductor package in FIG. 1.

FIG. 4 is a plan view illustrating a front surface of a fourth semiconductor chip of FIG. 1.

FIGS. 5 to 14 are views illustrating a method of manufacturing a semiconductor package in accordance with example embodiments.

FIGS. 15A to 15D are plan views illustrating bonding pads having various shapes.

FIG. 16 is a cross-sectional view illustrating a chip pad of a fourth semiconductor chip of a semiconductor package according to example embodiments.

FIG. 17 is a cross-sectional view illustrating a semiconductor package in accordance with example embodiments.

FIG. 18 is an enlarged cross-sectional view illustrating portion ‘C’in FIG. 17.

FIG. 19 is a bottom view illustrating a sealing member of the semiconductor package of FIG. 17.

FIG. 20 is a plan view illustrating a front surface of a fourth semiconductor chip of FIG. 17.

FIGS. 21 to 28 are views illustrating a method of manufacturing a semiconductor package in accordance with example embodiments.

FIGS. 29A to 29D are plan views illustrating bonding pads and connection wirings having various shapes.

### DETAILED DESCRIPTION

Hereinafter, example embodiments will be explained in detail with reference to the accompanying drawings. In all figures in this specification, directions indicated by an arrow and a reverse direction thereto are considered as the same direction.

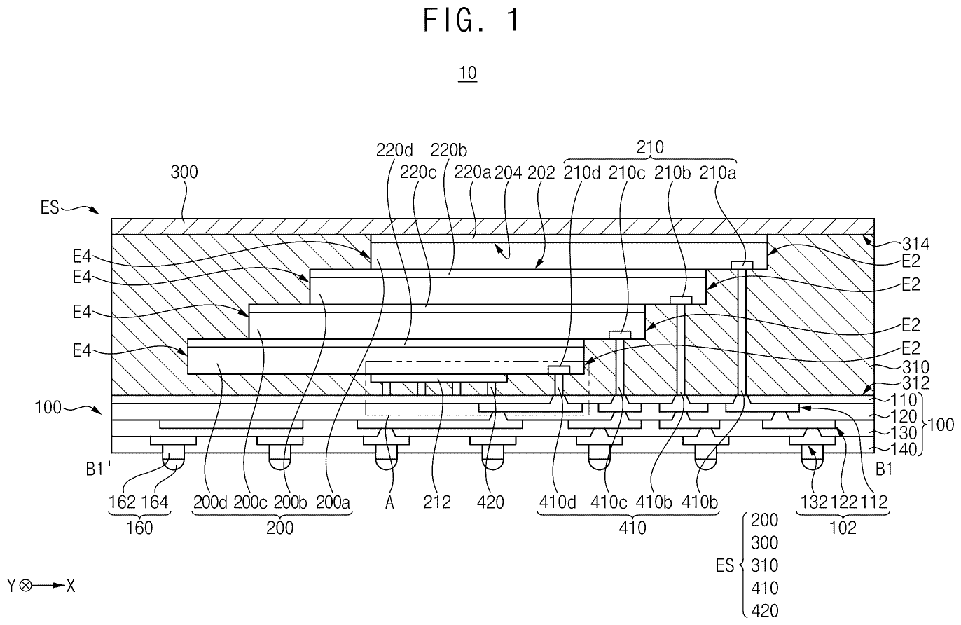

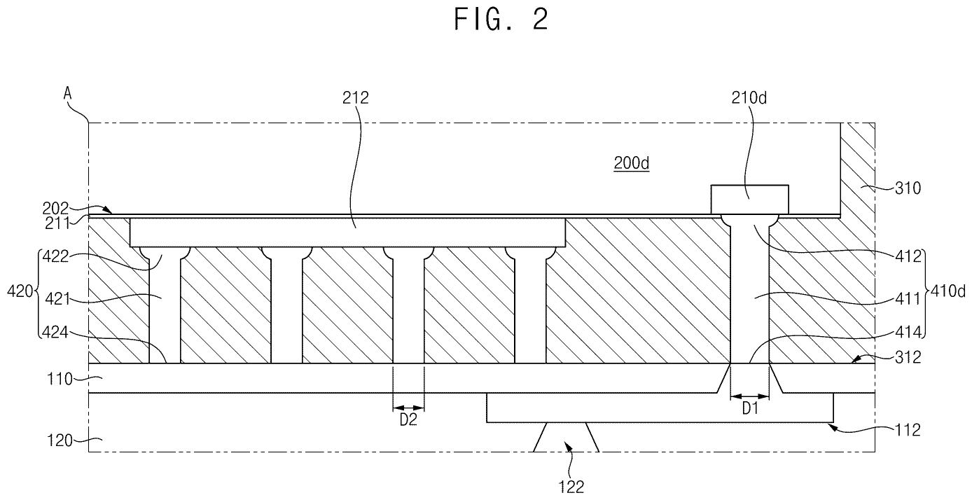

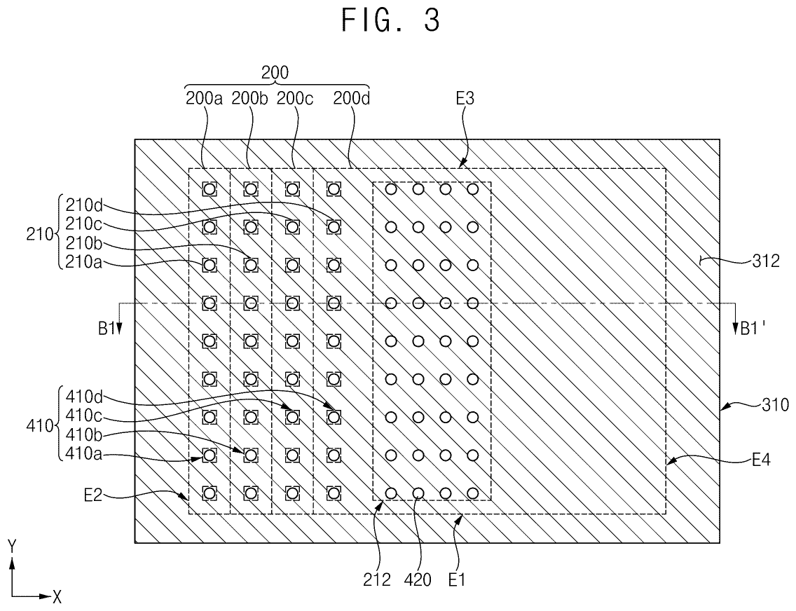

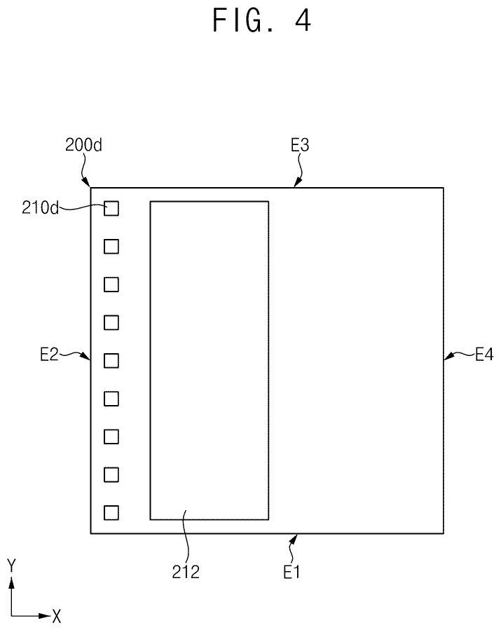

FIG. 1 is a cross-sectional view illustrating a semiconductor package in accordance with example embodiments. FIG. 2 is an enlarged cross-sectional view illustrating portion ‘A’ in FIG. 1. FIG. 3 is a bottom view illustrating a sealing member of the semiconductor package in FIG. 1. FIG. 4 is a plan view illustrating a front surface of a fourth semiconductor chip of FIG. 1. FIG. 1 includes a cross-section taken along the line B1-B1′ in FIG. 3.

Referring to FIGS. 1 to 4, a semiconductor package 10 may include a redistribution wiring layer 100 and an encapsulation structure ES disposed on the redistribution wiring layer 100. Additionally, the semiconductor package 10 may further include external connection members 160 disposed on an outer side surface of the redistribution wiring layer 100. The encapsulation structure ES may include a sealing member 310 having a first surface 312 and a second surface 312 opposite to the first surface 312, a plurality of semiconductor chips 200 disposed in the sealing member 310, first conductive wires in the sealing member 310 and extending vertically from chip pads 210 of the plurality of semiconductor chips 200, and second conductive wires 420 in the sealing member 310 and extending vertically from bonding pads 212 of the lowest semiconductor chip 200d of the plurality of semiconductor chips 200. Additionally, the encapsulation structure ES may further include a protective layer 300 disposed on the second surface 314 of the sealing member 310.

In example embodiments, the semiconductor package 10 may be a fan-out package in which the redistribution wiring layer 100 is formed to extend beyond a region where the semiconductor chip 200 are arranged. The redistribution wiring layer 100 may be formed by a wafer-level redistribution wiring process. In addition, the semiconductor package 10 may be provided as an upper package that is stacked on a lower package.

Additionally, the semiconductor package 10 may be provided as a System In Package (SIP). For example, one or more semiconductor chips may be disposed on the redistribution wiring layer 100. The semiconductor chips may include a logic chip including a logic circuit and/or a memory chip. The logic chip may be a controller that controls memory chips. The memory chip includes various types of memory circuits, such as DRAM, SRAM, flash, PRAM, ReRAM, FeRAM, or MRAM.

In example embodiments, the redistribution wiring layer 100 may have redistribution wirings 102. The encapsulation structure ES including the plurality of semiconductor chips 200 electrically connected to the redistribution wirings 102 therein may be stacked on the redistribution wiring layer 100. The redistribution wiring layer 100 may be a front redistribution wiring layer (FRDL) of the fan-out package.

In particular, the redistribution wiring layer 100 may include a plurality of insulating layers, i.e., first, second, third and fourth lower insulating layers 110, 120, 130 and 140 and the redistribution wirings 102 provided in the first, second, third and fourth lower insulating layers. The redistribution wirings 102 may include first, second and third redistribution wirings 112, 122 and 132.

The first, second, third and fourth lower insulating layers may include a polymer, a dielectric layer, etc. For example, the first, second, third and fourth lower insulating layers may include a photosensitive insulating layer such as PID (photo imagable dielectric. The first, second, third and fourth lower insulating layers may be formed by a vapor deposition process, a spin coating process, etc. The redistribution wirings may include aluminum (Al), copper (Cu), tin (Sn), nickel (Ni), gold (Au), platinum (Pt), or an alloy thereof. The redistribution wirings may be formed by a plating process, an electroless plating process, a vapor deposition process, etc.

In particular, the first lower insulating layer 110 may be formed on the first surface 312 of the sealing member 312, and the first redistribution wirings 112 may be formed on the first lower insulating layer 110. The first redistribution wirings 112 may be electrically connected to the first conductive wires 410 that are exposed from the first surface 312 of the sealing member 310, through first openings formed in the first lower insulating layer 120.

The second lower insulating layer 120 may be formed on the first lower insulating layer 110, and the second redistribution wirings 122 may be formed on the second lower insulating layer 120. The second redistribution wirings 122 may be electrically connected to the first redistribution wirings 112 through second openings formed in the second lower insulating layer 120.

The third lower insulating layer 130 may be formed on the second lower insulating layer 120, and the third redistribution wirings 132 may be formed on the third lower insulating layer 130. The third redistribution wirings 132 may be electrically connected to the second redistribution wirings 122 through third openings formed in the third lower insulating layer 130.

The fourth lower insulating layer 140 may be formed on the third lower insulating layer 130 to expose at least portions of the third redistribution wirings 132. The fourth lower insulating layer 140 may serve as a passivation layer.

It will be understood that the number, size, arrangement, etc. of the lower insulating layers and the redistribution wirings of the redistribution wiring layer are provided as an example, and the present inventive concept is not limited thereto.

In example embodiments, when viewed in a plan view, the redistribution wiring layer 100 may include a first region overlapping the semiconductor chips 200 of the encapsulation structure ES disposed on an upper surface of the redistribution wiring layer 100 and a second region surrounding the first region. The second region may be a fan-out region outside the region where the semiconductor chips are disposed.

In example embodiments, the encapsulation structure ES may include the sealing member 310 provided on the redistribution wiring layer 100. The first surface 312 of the sealing member 310 may be in contact with the redistribution wiring layer 100. The encapsulation structure ES may further include the protective layer 300 on the second surface 314 of the sealing member 310.

The plurality of semiconductor chips 200 may be sequentially stacked within the sealing member 310. The plurality of semiconductor chips 200 may be arranged such that a front surface 202 on which the chip pads 210 are formed faces the redistribution wiring layer 100. Each of the semiconductor chips 200 may have a rectangular shape with four sides when viewed in plan view. A first side surface E1 and a third side surface E3 of each of the semiconductor chips 200 may be arranged to be parallel to a first direction (X direction) and a second side surface E2 and a fourth side surface E4 of each of the semiconductor chips 200 may be arranged to be parallel to a second direction (Y direction) perpendicular to the first direction. The chip pads 210 may be disposed in a peripheral region along one side surface (E2 of each of the semiconductor chips 200.

In particular, the plurality of semiconductor chips 200 may include first, second, third, and fourth semiconductor chips 200a, 200b, 200c, and 200d stacked in a cascade structure from the protective layer 300. The first, second, third, and fourth semiconductor chips 200a, 200b, 200c, and 200d may be sequentially attached to a surface of the protective layer 300 using adhesive films 220. The adhesive films may include a die attach film (DAF). For example, a thickness of the semiconductor chip may be within a range of 40 μm to 110 μm. A thickness of the adhesive film may be within a range of 10 μm to 60 μm.

The second semiconductor chip 200b may be offset aligned in a first horizontal direction (X direction) with respect to the first semiconductor chip 200a. The second semiconductor chip 200b may be offset aligned in the first horizontal direction such that the chip pads 210a of the first semiconductor chip 200a are exposed from the second semiconductor chip 200b. The third semiconductor chip 200c may be offset aligned in the first horizontal direction with respect to the second semiconductor chip 200b. The third semiconductor chip 200c may be offset aligned in the first horizontal direction such that the chip pads 210b of the second semiconductor chip 200b are exposed from the third semiconductor chip 200c. The fourth semiconductor chip 200d may be offset aligned in the first horizontal direction with respect to the third semiconductor chip 200c. The fourth semiconductor chip 200d may be offset aligned in the first horizontal direction such that the chip pads 210c of the third semiconductor chip 200c are exposed from the fourth semiconductor chip 200d.

Each of the first, second, and third semiconductor chips 200a, 200b, and 200c may have an overhang portion protruding from one side of each of the underlying second, third, and fourth semiconductor chips 200b, 200c, and 200d. When viewed from bottom view of FIG. 3, the chip pads 210a of the first semiconductor chip 200a may be arranged on a lower surface (that is, the front surface 202 of the overhang portion protruding from one side surface E2 of the second semiconductor chips 200b to be spaced apart from one another along a second horizontal direction (Y direction) perpendicular to the first horizontal direction. When viewed from bottom view, the chip pads 210b of the second semiconductor chip 200b may be arranged on a lower surface (that is, the front surface 202 of the overhang portion protruding from one side surface E2 of the third semiconductor chips 200c to be spaced apart from one another along the second horizontal direction. When viewed from bottom view, the chip pads 210c of the third semiconductor chip 200c may be arranged on a lower surface (that is, the front surface 202 of the overhang portion protruding from one side surface E2 of the fourth semiconductor chip 200d to be spaced apart from one another along the second horizontal direction.

In example embodiments, the semiconductor package 10 may include the bonding pad 212 formed on the front surface 202 of the fourth semiconductor chip 200d as the lowest semiconductor chip closest to the redistribution wiring layer 100. The bonding pad 212 may be arranged to be spaced apart from the chip pads 210d in the first horizontal direction (X direction). The bonding pad 212 may serve as a landing pad that provides a plane on which one end portions of the second conductive wires are bonded.

As illustrated in FIG. 2, the bonding pad 212 may be a conductive pattern formed on an upper protective layer 211 that is formed on the front surface 202 of the fourth semiconductor chip 200d. The upper protective layer 211 may have an opening that exposes at least a portion of the chip pad 210d. The bonding pad 212 may be positioned on the upper protective layer 211 and spaced apart from the opening of the upper protective layer 211. For example, the bonding pad 212 may include a metal pattern and at least one plating pattern layer formed on the metal pattern. The metal pattern may include a metal material such as copper (Cu). The plating pattern layer may include nickel (Ni), gold (Au), etc. The bonding pad 212 may be formed by a wafer-level redistribution wiring process. For example, the chip pad 210d may include a conductive metal such as copper (Cu) or aluminum (Al), and the upper protective layer 211 may include a resin such as photosensitive polyimide (PSPI).

As illustrated in FIGS. 3 and 4, the bonding pad 212 may have a rectangular shape. The bonding pad 212 may have a single pad shape extending in the second horizontal direction (Y direction). The bonding pad 212 may provide a pad region where one end portions of a plurality of bonding wires are bonded. However, the shape of the bonding pad 212 may not be limited thereto, and may have various shapes to provide a plane where one end portions of the bonding wires are bonded.

The plurality of semiconductor chips 200 may include a memory chip including a memory circuits. For example, the semiconductor chip may include volatile memory devices such as SRAM devices or DRAM devices, and non-volatile memory devices such as flash memory devices, PRAM devices, MRAM devices or RRAM devices.

It will be understood that the number, size, arrangement, etc. of the semiconductor chips are provided as an example, and the present inventive concept is not limited thereto. Also, although only a few chip pads are illustrated in the figures, it will be understood that the structure, shape, and arrangement of the chip pads are provided as an example, and the present inventive concept is not limited thereto.

In example embodiments, the first conductive wires 410 as a plurality of vertical conductive structures may extend vertically on the chip pads 210 of the first, second, third, and fourth semiconductor chips 200 within the sealing member 310, respectively. When viewed from bottom view, the first conductive wires 410 may be positioned in the region where the plurality of semiconductor chips 200 are disposed.

In particular, the first conductive wires 410a may be conductive wires that extend from the chip pads 210a of the first semiconductor chip 200a to the first surface 312 of the sealing member 310 in a vertical direction (Z direction), respectively. The first conductive wires 410b may be conductive wires that extend from the chip pads 210b of the second semiconductor chip 200b to the first surface 312 of the sealing member 310 in the vertical direction (Z direction), respectively. The first conductive wires 410c may be conductive wires that extend from the chip pads 210c of the third semiconductor chip 200c to the first surface 312 of the sealing member 310 in the vertical direction (Z direction), respectively. The first conductive wires 410d may be conductive wires that extend from the chip pads 210d of the fourth semiconductor chip 200d to the first surface 312 of the sealing member 310 in the vertical direction (Z direction), respectively.

As illustrated in FIG. 2, the first conductive wire 410d may include a first wire body 411 extending in the vertical direction, a first bonding end portion 412 provided at a first end portion of the first wire body 411 and bonded to the chip pad 210d, and a second bonding end portion 414 provided at a second end portion of the first wire body 411 opposite to the first end portion. Each of the second conductive wires 420 may include a second wire body 421 extending in the vertical direction, a third bonding end portion 422 provided at a first end portion of the second wire body 421 and bonded to the bonding pad 212, and a fourth bonding end portion 424 provided at the second end portion of the second wire body 421. The second bonding end portion of each of the first conductive wires 410 and the fourth bonding end portion of each of the second conductive wires 420 may be exposed by the first surface 312 of the sealing member 310.

The number of the first conductive wires 410 may be the same as the number of the second conductive wires 420. A diameter D1 of each of the first conductive wires 410 may be the same as a diameter D2 of each of the second conductive wires 420. Each of the first conductive wires 410 and the second conductive wires 420 may have a diameter within a range of 13 μm to 40 μm. The first and second conductive wires may be formed by a bonding wire process. For example, the first and second conductive wires may include copper (Cu), gold (Au), aluminum (Al), etc. The diameters D1, D2 of the first and second wire bodies 411, 421 may be within a range of 13 μm to 40 μm. A width (diameter) of the chip pad 210 may be within a range of 40 μm to 70 μm.

In example embodiments, the sealing member 310 may include a thermosetting resin, for example, epoxy molding compound (EMC. The sealing member 310 may include fillers as fillers and an epoxy resin that acts as a binder for the fillers. The protective layer 300 may include a sealing film. The sealing film may include various types of fillers and resins to protect the semiconductor chips from an external environment. For example, the protective layer 300 may include an epoxy molding compound (EMC film that is processed into a film form. The protective layer 300 may have a thickness of approximately several micrometers (μm) to several tens of μm.

In example embodiments, the external connection members 160 may be disposed on a lower surface of the redistribution wiring layer 100. For example, each of the external connection members 160 may include a pillar bump 162 formed on a lower bonding pad on the third redistribution wiring 132 exposed by the fourth lower insulating layer 140 and a solder bump 164 on the pillar bump 162. For example, the pillar bump may include copper (Cu), aluminum (Al), tin (Sn), nickel (Ni), gold (Au), platinum (Pt), or an alloy thereof. The solder bump may include solder. The semiconductor package 10 may be mounted on a lower package, an interposer, a package substrate, etc. via the external connection members 160 to form a package-on-package (POP) device.

As mentioned above, the semiconductor package 10 may include the redistribution wiring layer 100 and the encapsulation structure ES stacked on the redistribution wiring layer 100. The encapsulation structure ES may include the sealing member 310, the plurality of semiconductor chips 200 arranged within the sealing member 310, the first conductive wires 410 extending vertically from the first surface 312 of the sealing member 310 to the chip pads 210 of the semiconductor chips 200 to be electrically connected to the redistribution wirings 102 of the redistribution wiring layer 100, and the second conductive wires 420 extending vertically from the first surface 312 of the sealing member 310 to the bonding pad 212 on the lowest semiconductor chip 200d.

After forming a plurality of bonding wires that connect the chip pads 210 of the semiconductor chips 200 and the bonding pad 212 of the fourth semiconductor chip 200d, the molding member 310 may be formed to cover the semiconductor chips 200 and the plurality of bonding wires. Then, when removing an upper portion of the molding member 310, portions of the plurality of bonding wires may be removed together to simultaneously form the first conductive wires 410 and the second conductive wires 420 within the molding member 310. Accordingly, after forming the vertical wires on the chip pads, the molding process may be performed to form the molding member 310, the phenomenon of the wires being tilted (wire sweep or wire sagging) due to a flow of a molding material during the molding process may be prevented, to thereby prevent wire short defects. Thus, pitches and diameters of the wires may be formed to be smaller.

Hereinafter, a method of manufacturing the semiconductor package of FIG. 1 will be described.

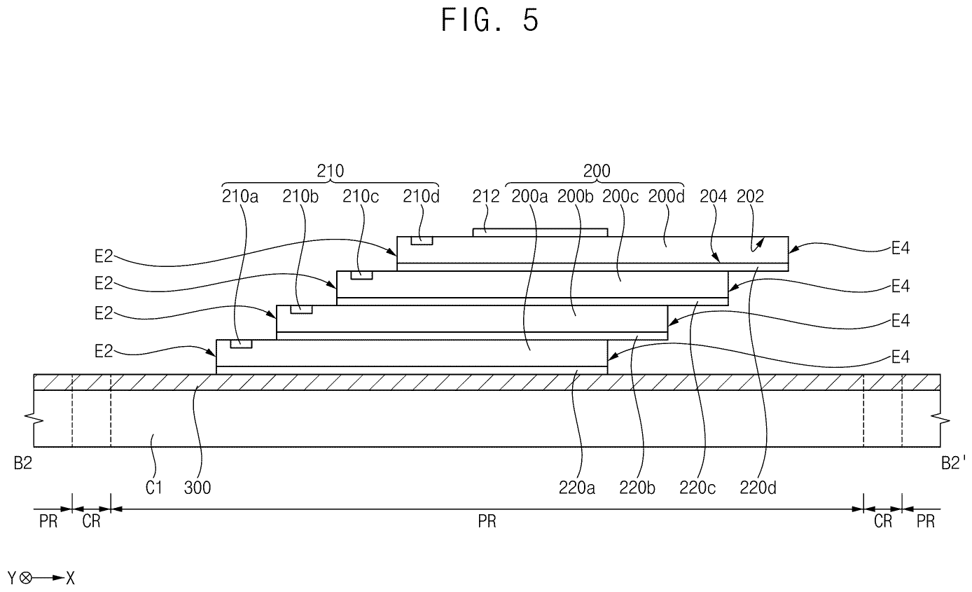

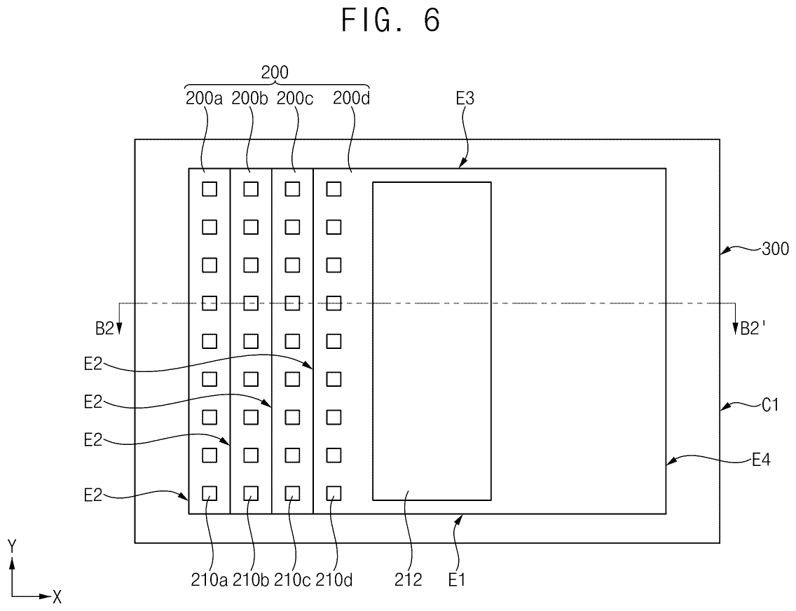

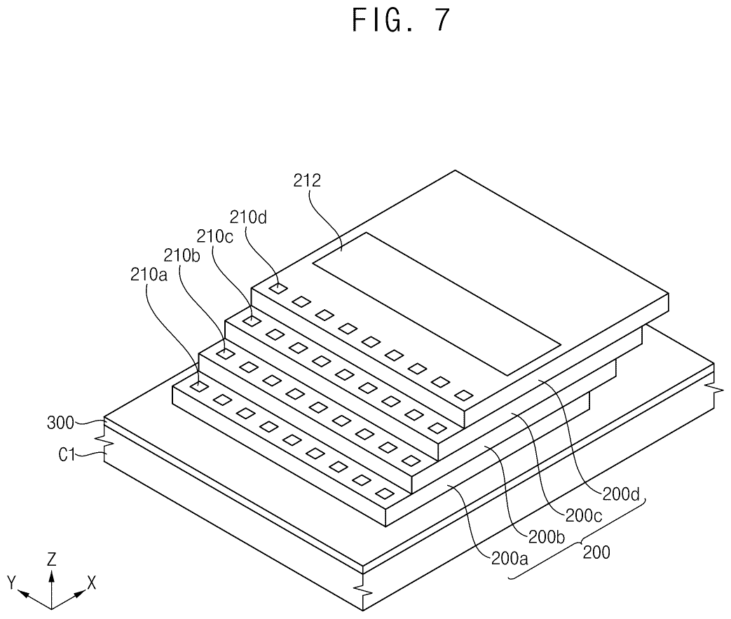

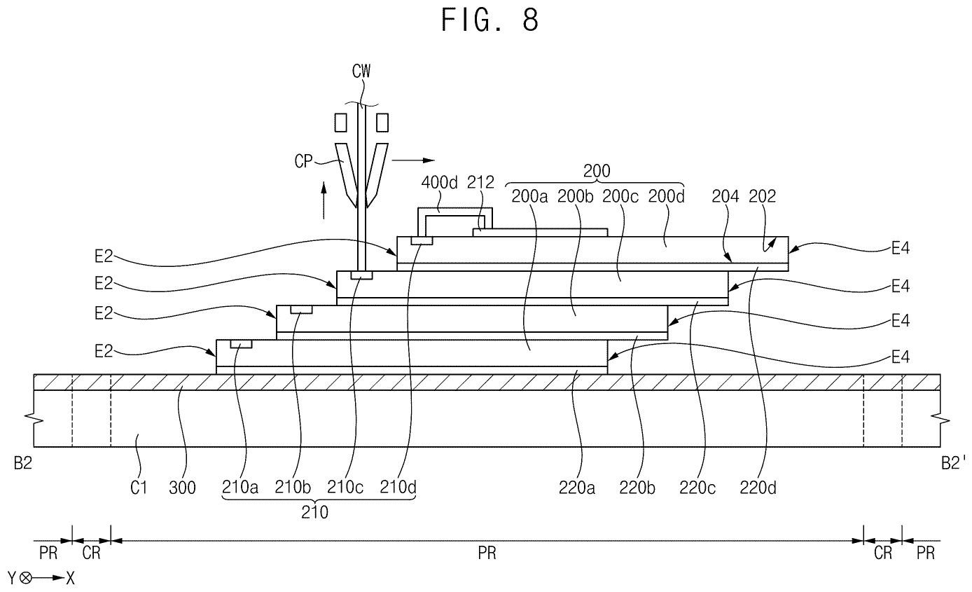

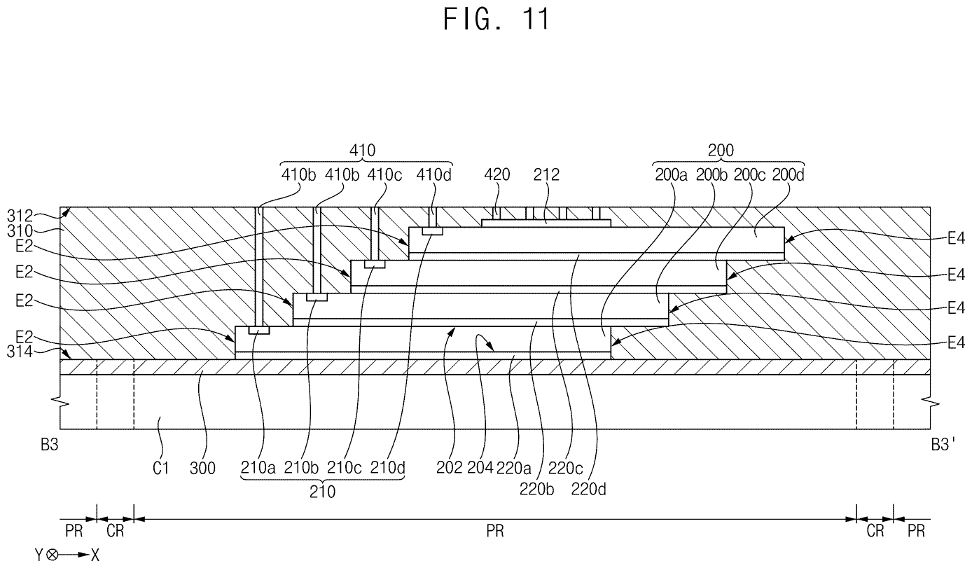

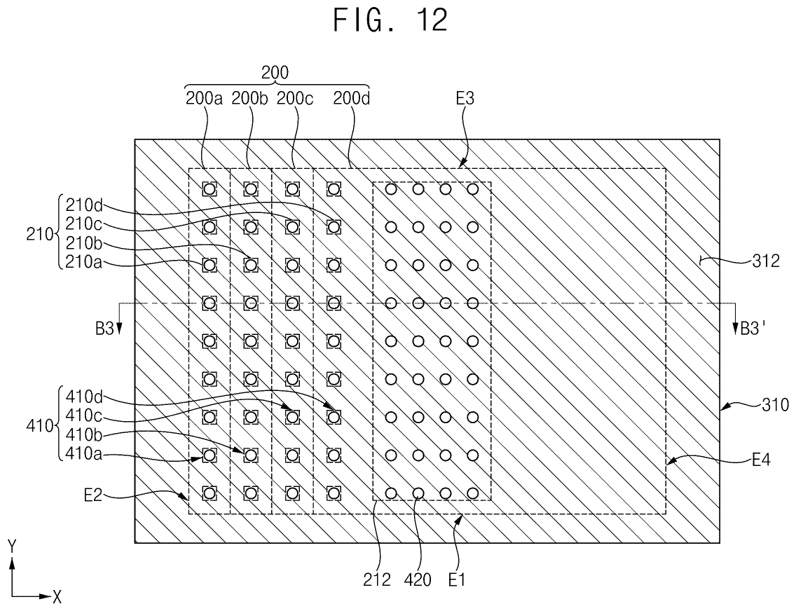

FIGS. 5 to 14 are views illustrating a method of manufacturing a semiconductor package in accordance with example embodiments. FIGS. 5, 8 to 11, 13 and 14 are cross-sectional views illustrating a method of manufacturing a semiconductor package in accordance with example embodiments. FIG. 6 is a plan view of FIG. 5. FIG. 7 is a perspective view of FIG. 5. FIG. 5 is a cross-sectional view taken along the B2-B2′ in FIG. 6. FIG. 8 is a perspective view of FIG. 7. FIG. 12 is a plan view of FIG. 11. FIG. 11 is a cross-sectional view taken along the B3-B3′ in FIG. 12.

Referring to FIGS. 5 to 8, a protective layer 300 may be formed on a first carrier substrate C1, and a plurality of semiconductor chips 200 may be stacked on the protective layer 300.

In example embodiments, the first carrier substrate C1 may be provided as a base substrate on which the plurality of semiconductor chips 200 are stacked, a sealing member is formed and a redistribution wiring layer is formed. The first carrier substrate C1 may have a shape corresponding to a wafer on which semiconductor manufacturing processes are performed. For example, the first carrier substrate C1 may include a glass substrate, a silicon substrate, a non-metallic or metallic plate, etc.

The first carrier substrate C1 may include a package region PR in which the semiconductor chips are arranged and a cutting region CR surrounding the package region PR. As described below, the sealing member and the redistribution wiring layer formed on the first carrier substrate C1 may be cut along the cutting region CR that divides the plurality of package regions PR to be individualized.

In example embodiments, the protective layer 300 may be formed by attaching a sealant film on the first carrier substrate C1 by a lamination process. The sealant film may include various forms of fillers and a resin to protect the semiconductor chips in the semiconductor package from an external environment. For example, the protective layer 300 may include an epoxy molding compound (EMC film that is processed into a film form. The protective layer 300 may have a thickness of approximately several micrometers (μm) to several tens of μm.

In example embodiments, four semiconductor chips 200a, 200b, 200c and 200d may be sequentially stacked on the first carrier substrate C1. Individual semiconductor chips diced from a wafer by a dicing process may be provided as the semiconductor chips.

The semiconductor chips 200a, 200b, 200c and 200d may be sequentially attached onto the protective layer 300 on the first carrier substrate C1 using adhesive films 220a, 220b, 220c, and 220d. The semiconductor chips 200a, 200b, 200c and 200d may be sequentially attached to the protective layer 300 using the adhesive films such as a die attach film (DAF) by a die attach process. For example, a thickness of the semiconductor chip may be within a range of 40 μm to 110 μm. A thickness of the adhesive film may be within the range of 10 μm to 60 μm.

The semiconductor chips 200a, 200b, 200c, and 200d may be arranged such that a backside surface 204 opposite to a front surface 322 on which chip pads 210a, 210b, 210c, and 210d are formed, that is, an inactive surface faces the first carrier substrate C1. Each of the semiconductor chips 200a, 200b, 200c, and 200d may have a quadrangular shape having four sides when viewed in plan view. A first side surface El and a third side surface E3 of each of the semiconductor chips may be arranged to be parallel to a first direction (X direction), and a second side surface E2 and a fourth side surface E4 of each of the semiconductor chips may be arranged to be parallel to a second direction (Y direction) perpendicular to the first direction. The chip pads 210a, 210b, 210c, and 210d (collectively 210 may be disposed in a peripheral region along one side (second side surface) of each of the semiconductor chips 200a, 200b, 200c and 200d. The chip pads 210 may be arranged to be spaced apart from one another in the second direction (Y direction) on the front surface 202 of each of the semiconductor chips 200a, 200b, 200c, and 200d.

In example embodiments, the semiconductor chips 200a, 200b, 200c and 200d may be stacked in a cascade structure on the first carrier substrate C1. The second semiconductor chip 200b may be aligned with an offset in a first horizontal direction (X direction) on the first semiconductor chip 200a. The second semiconductor chip 200b may be offset aligned in the first horizontal direction such that the chip pads 210a of the first semiconductor chip 200a are exposed from the second semiconductor chip 200b. The third semiconductor chip 200c may be aligned with an offset in the first horizontal direction on the second semiconductor chip 200b. The third semiconductor chip 200c may be offset aligned in the first horizontal direction such that the chip pads 210b of the second semiconductor chip 200b are exposed from the third semiconductor chip 200c. The fourth semiconductor chip 200d may be aligned with an offset in the first horizontal direction on the third semiconductor chip 200c. The fourth semiconductor chip 200d may be offset aligned in the first horizontal direction such that the chip pads 210c of the third semiconductor chip 200c are exposed from the fourth semiconductor chip 200d.

Each of the first, second, and third semiconductor chips 200a, 200b, and 200c may have an overhang portion protruding from one side of each of the overlying second, third, and fourth semiconductor chips 200b, 200c, and 200d. When viewed in plan view, the chip pads 210a of the first semiconductor chip 200a may be arranged on an upper surface (that is, the front surface 202 of the overhang portion protruding from one side surface E2 of the second semiconductor chips 200b to be spaced apart from one another along a second horizontal direction (Y direction) perpendicular to the first horizontal direction. When viewed in plan view, the chip pads 210b of the second semiconductor chip 200b may be arranged on an upper surface (that is, the front surface 202 of the overhang portion protruding from one side surface E2 of the third semiconductor chips 200c to be spaced apart from one another along the second horizontal direction. When viewed in plan view, the chip pads 210c of the third semiconductor chip 200c may be arranged on an upper surface (that is, the front surface 202 of the overhang portion protruding from one side surface E2 of the fourth semiconductor chip 200d to be spaced apart from one another along the second horizontal direction.

In example embodiments, the fourth semiconductor chip 200d as the uppermost semiconductor chip may include a bonding pad 212 on the front surface 202 thereof. The bonding pad 212 may be spaced apart from the chip pads 210d in the first horizontal direction (X direction). The bonding pad 212 may serve as a landing pad that provides a plane on which end portions of bonding wires extending from the chip pads are bonded, as described below.

For example, a redistribution wiring process may be performed on a wafer on which a plurality of fourth semiconductor chips are formed, to form the bonding pad 212 on the front surface of each of the fourth semiconductor chips. Then, the wafer may be cut to form individual fourth semiconductor chips 200d, and the fourth semiconductor chip 200d may be offset aligned on the third semiconductor chip 200c in the first horizontal direction. The bonding pad 212 may be a conductive pattern formed on an upper protective layer formed on the front surface of the fourth semiconductor chip. For example, the bonding pad 212 may include a metal pattern and at least one plating pattern layer formed on the metal pattern. The metal pattern may include a metal material such as copper (Cu). The plating pattern layer may include nickel (Ni), gold (Au), etc.

As illustrated in FIG. 6, the bonding pad 212 may have a rectangular shape. The bonding pad 212 may have a single pad shape extending in the second horizontal direction (Y direction). The bonding pad 212 may provide a pad region where end portions of a plurality of bonding wires are bonded. However, the shape of the bonding pad 212 may not be limited thereto, and may have various shapes to provide a plane where end portions of the bonding wires are bonded.

The semiconductor chip may include a memory chip including a memory circuits. For example, the semiconductor chip may include volatile memory devices such as SRAM devices or DRAM devices, and non-volatile memory devices such as flash memory devices, PRAM devices, MRAM devices or RRAM devices.

It will be understood that the number, size, arrangement, etc. of the semiconductor chips are provided as an example, and the present inventive concept is not limited thereto. Also, although only a few chip pads are illustrated in the figures, it will be understood that the structure, shape, and arrangement of the chip pads are provided as an example, and the present inventive concept is not limited thereto.

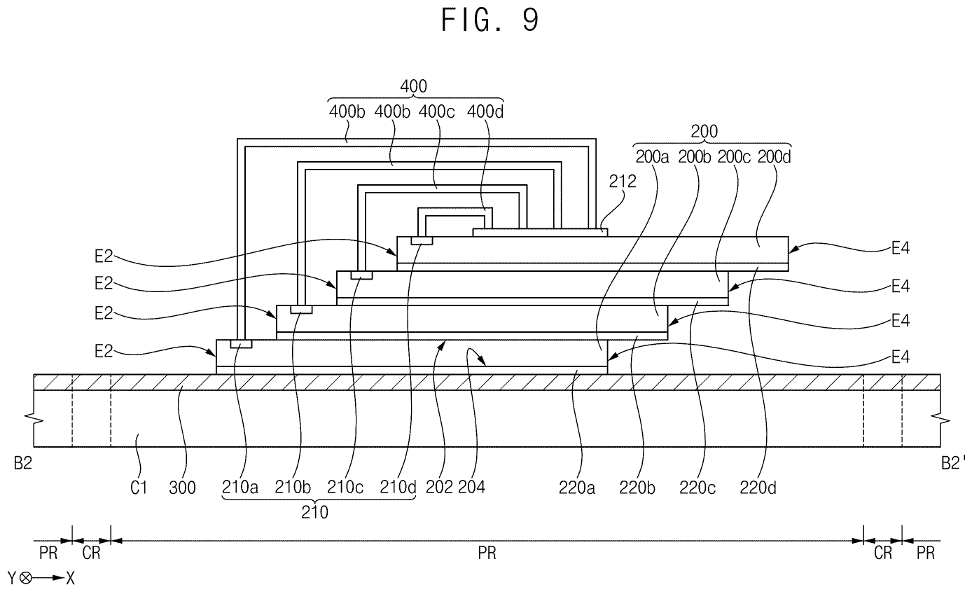

Referring to FIGS. 8 and 9, a plurality of bonding wires 400 may be formed to connect the chip pads 210 of the semiconductor chip 200 to the bonding pads 212 of the fourth semiconductor chip 200d using a wire bonding apparatus.

As illustrated in FIG. 8, a free air ball (FAB may be formed at one end of a wire CW drawn from a capillary CP of the wire bonding apparatus, and after bonding to the chip pad 210 of the semiconductor chip 200, the capillary CP may move vertically to draw out the wire. Then, when the wire extends to a preset length, the capillary CP may move to the bonding pad 212 and descend to bring the wire into contact with a surface of the bonding pad 212, and then a portion of the wire may be cut. The bonding wire process may then be continued by moving to another chip pad.

For example, a fourth bonding wire 400d may be formed to extend from the chip pad 210d of the fourth semiconductor chip 200d to the bonding pad 212. Then, a third bonding wire 400c may be formed to extend from the chip pad 210c of the third semiconductor chip 200c spaced apart in the first horizontal direction to the bonding pad 212. Similarly, a second bonding wire 400b may be formed to extend from the chip pad 210b of the second semiconductor chip 200b spaced apart in the first horizontal direction to the bonding pad 212, and a first bonding wire 400a may be formed to extend from the chip pad 210a of the first semiconductor chip 200a spaced apart in the first horizontal direction to the bonding pad 212.

Each of the plurality of bonding wires 400 may include a first portion extending vertically from the chip pad 210 of the semiconductor chip 200, a second portion extending vertically from the bonding pad 212, and a third portion extending horizontally (in the first horizontal direction) connecting the first portion and the second portion.

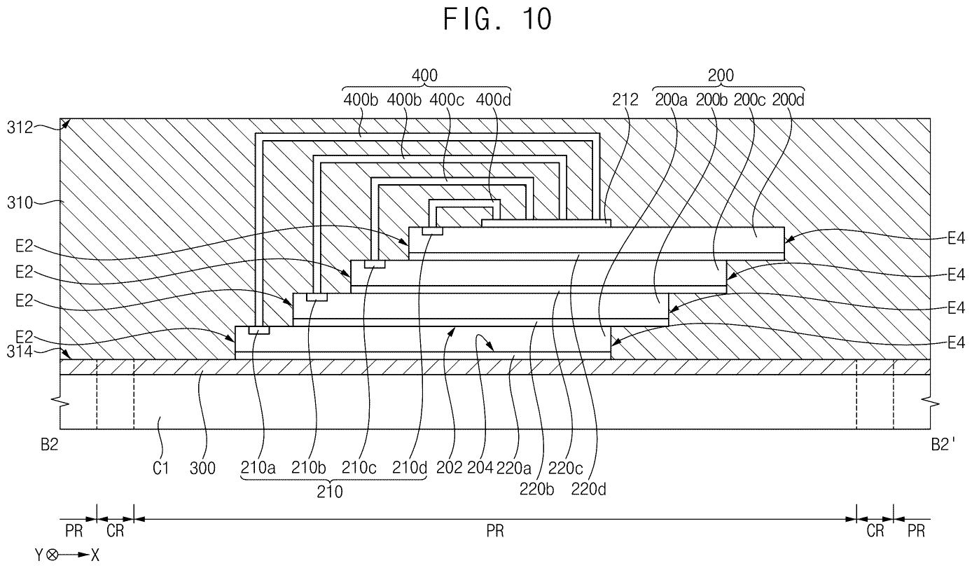

Referring to FIG. 10, a sealing member 310 may be formed on the protective layer 300 on the first carrier substrate C1 to cover the plurality of semiconductor chips 200 and the plurality of bonding wires 400.

In exemplary embodiments, a sealing material may be formed on an upper surface of the protective layer 300 to completely cover the plurality of semiconductor chips 200 and the plurality of bonding wires 400. The sealing member 310 may have a first surface 312 and a second surface 314 opposite to the first surface 312. The second surface 314 of the sealing member 310 may be in contact with the protective layer 300.

For example, the sealing member 310 may be formed on the first carrier substrate C1 using a transfer molding apparatus. The sealing member 310 may include a thermosetting resin, for example, epoxy mold compound (EMC. The sealing member 310 may include fillers as a filler and an epoxy resin that acts as a binder for the fillers.

Each of the plurality of bonding wires 400 may have a wire loop structure in which both end portions are bonded to the chip pad 210 and the bonding pad 212, to thereby prevent wire sweep due to the flow of the molding material (EMC during the molding process.

Referring to FIGS. 11 and 12, an upper portion of the sealing member 310 may be removed to form the sealing member 310 having a desired height. At this time, the plurality of bonding wires 400 may be partially removed to form first conductive wires 410 extending vertically from the chip pads 210 of the semiconductor chips 200 and second conductive wires 420 extending vertically from the bonding pad 212.

For example, the upper portion of the sealing member 310 may be removed by a grinding apparatus GA. At this time, a portion of each of the plurality of bonding wires 400 (including the third portion connecting the first portion and the second portion and extending horizontally (in the first horizontal direction)) may be removed together. The first portion of the bonding wire 400 extending vertically from the chip pad 210 of the semiconductor chip 200 may be formed as the first conductive wire 410, and the second portion extending vertically from the bonding pad 212 may be formed as the second conductive wire 420. Accordingly, end portions of the first and second conductive wires 410, 420 may be exposed from the first surface 312 of the sealing member 310.

The first conductive wires 410a may extend vertically from the chip pads 210a of the first semiconductor chip 200a, respectively. The first conductive wires 410b may extend vertically from the chip pads 210b of the second semiconductor chip 200b, respectively. The first conductive wires 410c may extend vertically from the chip pads 210c of the third semiconductor chip 200c, respectively. The first conductive wires 410d may extend vertically from the chip pads 210d of the fourth semiconductor chip 200d, respectively. The second conductive wires 420 may extend vertically from the bonding pad 212 of the fourth semiconductor chip 200d, respectively.

By removing a portion of one bonding wire 400, one first conductive wire 410 and one second conductive wire 420 may be formed. Accordingly, the number of the first conductive wires 410 may be the same as the number of the second conductive wires 420. A diameter of each of the first conductive wires 410 may be the same as a diameter of each of the second conductive wires 420. Each of the first conductive wires 410 and the second conductive wires 420 may have the diameter within a range of 13 μm to 40 μm.

Each of the first conductive wires 410 may include a first wire body extending in a vertical direction, a first bonding end portion provided at a first end portion of the first wire body and bonded to the chip pad 210, and a second bonding end portion provided at a second end portion of the first wire body. Each of the second conductive wires 420 may include a second wire body extending in the vertical direction, a third bonding end portion provided at a first end portion of the second wire body and bonded to the bonding pad 212, and a fourth bonding end portion provided at a second end portion of the second wire body. The second bonding end portion of each of the first conductive wires 410 and the fourth bonding end portion of each of the second conductive wires 420 may be exposed from the first surface 312 of the sealing member 310.

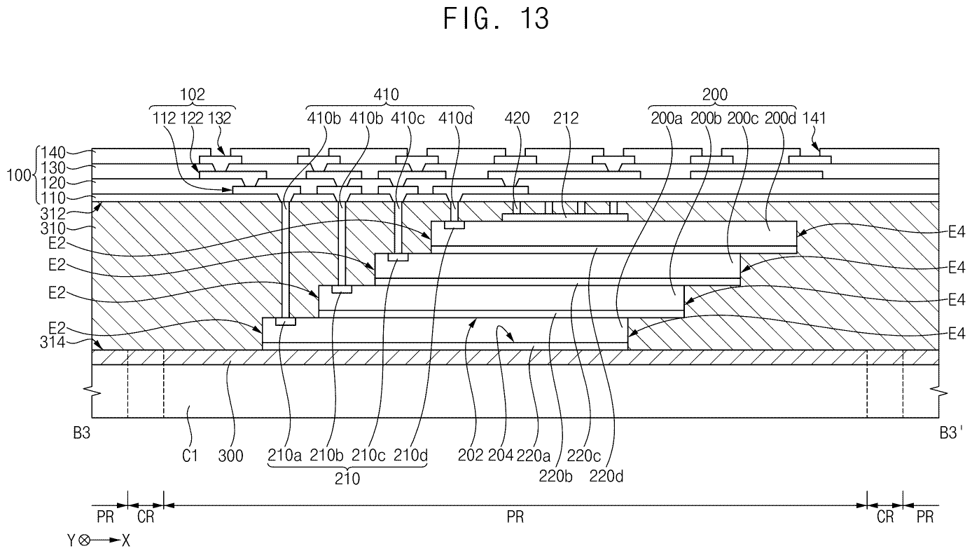

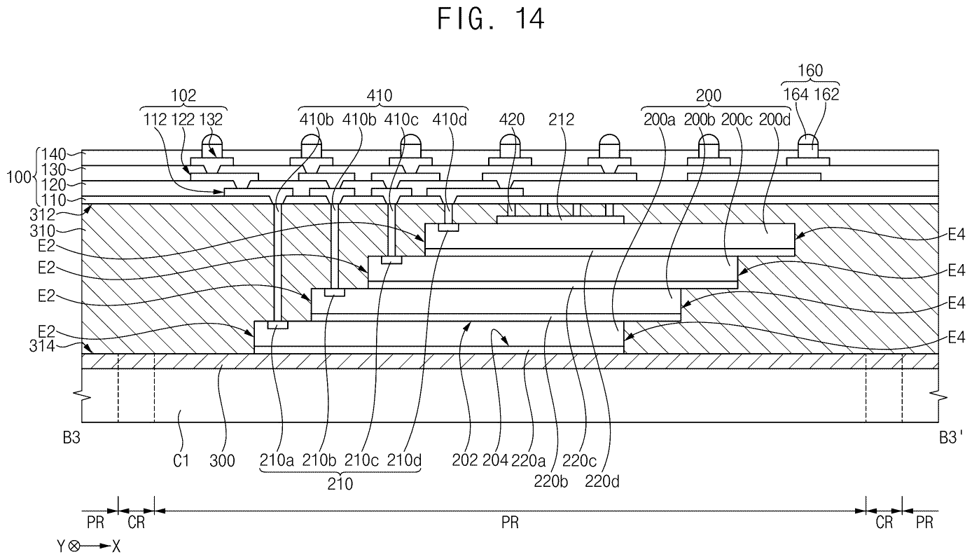

Referring to FIGS. 13 and 14, a redistribution wiring layer 100 may be formed on the first surface 312 of the sealing member 310, and a plurality of external connection members 160 may be formed on the redistribution wiring layer 100.

As illustrated in FIG. 13, the redistribution wiring layer 100 having redistribution wirings 102 electrically connected to the first conductive wires 410 may be formed on the first surface 312 of the sealing member 310.

In example embodiments, after a first lower insulating layer 110 is formed on the first surface 312 of the sealing member 310, the first lower insulating layer 110 may be patterned to form first openings. The first openings may expose the end portions of the first conductive wires 410, i.e., the second bonding end portions, respectively. The first lower insulating layer 110 may include a polymer, a dielectric layer, etc. The first lower insulating layer 110 may be formed by a vapor deposition process, a spin coating process, or the like.

Then, after a seed layer is formed on the exposed end portions of the first conductive wires 410 and in the first openings, the seed layer may be patterned and an electrolytic plating process may be performed to form first redistribution wirings 112. Accordingly, at least portions of the first redistribution wirings 112 may be electrically connected to the first conductive wires 410 through the first openings. The first redistribution wirings may include aluminum (Al), copper (Cu), tin (Sn), nickel (Ni), gold (Au), platinum (Pt), or an alloy thereof.

Similarly, after forming a second lower insulating layer 120 on the first lower insulating layer 110, the second lower insulating layer 120 may be patterned to form second openings that expose the first redistribution wirings 112 respectively. Then, second redistribution wirings 122 may be formed on the second lower insulating layer 120 to be electrically connected to the first redistribution wirings 112 through the second openings.

Similarly, after forming a third lower insulating layer 130 on the second lower insulating layer 120, the third lower insulating layer 130 may be patterned to form third openings that expose the second redistribution wirings 122 respectively. Then, third redistribution wirings 132 may be formed on the third lower insulating layer 130 to be electrically connected to the second redistribution wirings 122 through the third openings.

Then, a fourth lower insulating layer 140 may be formed on the third lower insulating layer 130 to cover the third redistribution wirings 132. The fourth lower insulating layer 140 may serve as a passivation layer. Then, the fourth lower insulating layer 140 may be partially removed by a via formation process to form openings 141 that expose portions of the third redistribution wirings 132. A lower bonding pad (not illustrated such as UBM may be formed on the portion of the third redistribution wiring 132 exposed by the fourth lower insulating layer 140 through a plating process.

Thus, the redistribution wiring layer 100 having the redistribution wirings 102 as a front redistribution layer (FRDL) may be formed on the sealing member 310. The redistribution wiring layer 100 may include the stacked first to fourth lower insulating layers 110, 120, 130, 140 and the redistribution wirings 102 in the first to fourth lower insulating layer 110, 120, 130, 140. The redistribution wirings 102 may include the first, second, and third redistribution wirings 112, 122, 132.

It will be understood that the number, size, arrangement, etc. of the insulating layers and the redistribution wirings of the redistribution wiring layer are provided as an example, and the present inventive concept is not limited thereto.

As illustrated in FIG. 14, the external connection members 160 electrically connected to the redistribution wirings 102, respectively, may be formed on the redistribution wiring layer 100.

In example embodiments, a seed layer and a photoresist layer may be formed on the fourth lower insulating layer 140, and an exposure process may be performed to form a photoresist pattern having openings that expose bump regions. Then, after filling the openings of the photoresist pattern with a conductive material, the photoresist pattern may be removed, and a reflow process may be performed to form the external connection members 160. Alternatively, the conductive bumps may be formed by a screen printing process, a deposition process, or the like.

For example, a pillar bump 162 may be formed on the lower bonding pad on the third redistribution wiring 132 exposed by the fourth lower insulating layer 140, and a solder bump 164 may be formed on the pillar bump 162. Accordingly, each of the external connection members 160 may include the pillar bump 162 and the solder bump 164 on the pillar bump 162. For example, the pillar bump may include copper (Cu), aluminum (Al), tin (Sn), nickel (Ni), gold (Au), platinum (Pt), or an alloy thereof. The solder bump may include solder.

Then, the redistribution wiring layer 100, the sealing member 310 and the protective layer 300 may be cut along the cutting region to complete a semiconductor package 10 of FIG. 1.

In example embodiments, the first carrier substrate C1 may be separated and removed from the protective layer 300, a dicing tape may be attached on the protective layer 300, and the dicing tape may be used to attach the structure to a lower surface of a ring frame. The redistribution wiring layer 100, the sealing member 310 and the protective layer 300 may be preliminarily cut along the cutting region CR, and the dicing tape may be expanded to separate the semiconductor packages 10 individually.

The redistribution wiring layer 100, the sealing member 310 and the protective layer 300 may be cut by a sawing process to form the semiconductor package 10 including the redistribution wiring layer 100 and an encapsulation structure ES stacked on the redistribution wiring layer 100. Accordingly, an outer side surface of the redistribution wiring layer 100 may be positioned on the same plane as an outer side surface of the sealing member 310. Additionally, the outer side surface of the sealing member 310 may be positioned on the same plane as an outer side surface of the protective layer 300.

As described above, after forming the plurality of bonding wires 400 connecting the chip pads 210 of the semiconductor chips 200 and the bonding pad 212 of the fourth semiconductor chip 200d, the molding member 310 may be formed to cover the semiconductor chips 200 and the plurality of bonding wires. Since the plurality of bonding wires 400 have a relatively stable loop structure, wire sweep and the like may be prevented from occurring during the molding process.

On the contrary, when vertical wires are formed on the chip pads 210 of the semiconductor chips 200 and then the molding process is performed, defects such as wire sweep may occur during the molding process because distal end portions of the vertical wires are not fixed.

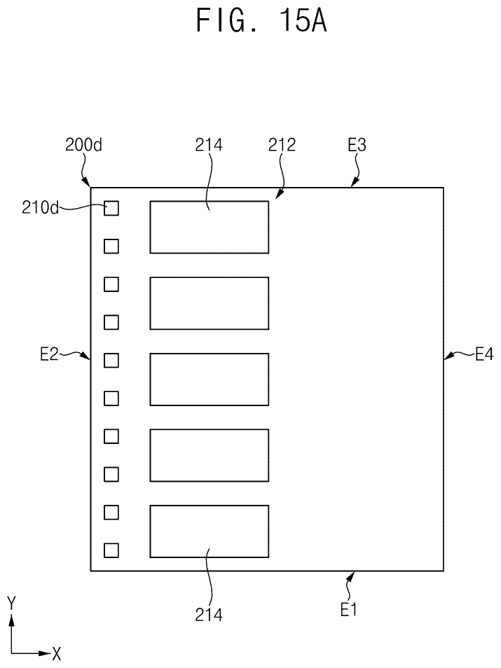

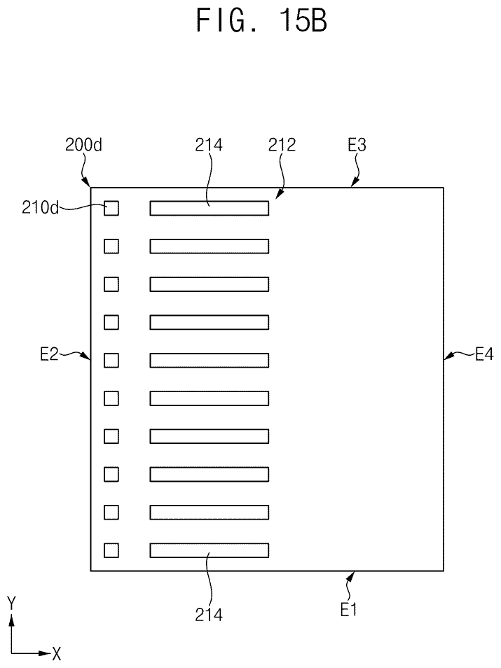

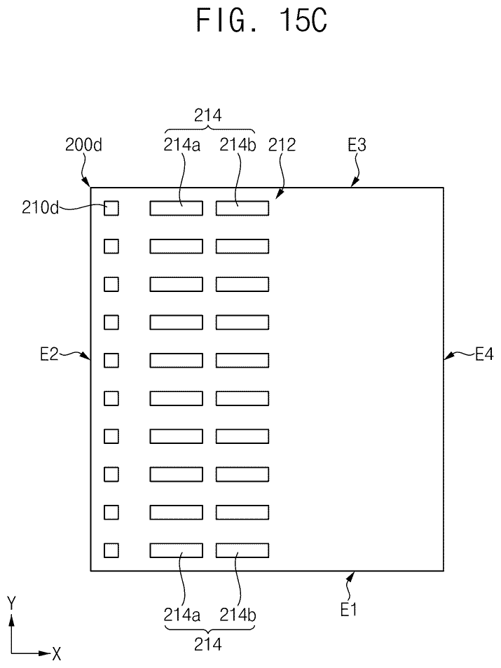

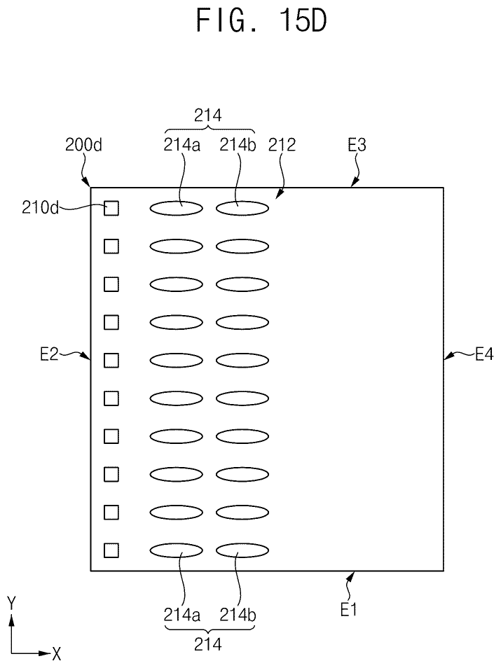

FIGS. 15A to 15D are plan views illustrating bonding pads having various shapes.

Referring to FIG. 15A, a bonding pad 212 provided on a front surface 202 of a fourth semiconductor chip 400d may include a plurality of bonding pad patterns 214 that are spaced apart from one another in a second horizontal direction (Y direction). Each bonding pad pattern 214 may extend in a first horizontal direction (X direction).

A width (length) of the bonding pad pattern 214 in the second direction may be determined in consideration of the number of bonding wires bonded to the bonding pad pattern 214.

For example, when forming the bonding wires 400 of FIG. 9, eight bonding wires spaced apart from one another in the second horizontal direction and extending from two adjacent chip pads 210 may be bonded to one bonding pad pattern 214.

Referring to FIG. 15B, a bonding pad 212 may include a plurality of bonding pad patterns 214 that are spaced apart from one another in a second horizontal direction (Y direction). Each bonding pad pattern 214 may extend in a first horizontal direction (X direction).

When forming the bonding wires 400 of FIG. 9, four bonding wires extending from the chip pads 210a, 210b, 210c, 210d of the first to fourth semiconductor chips 200a, 200b, 200c, 200d spaced apart from one another in the first horizontal direction may be bonded to one bonding pad pattern 214.

Referring to FIG. 15C, a bonding pad 212 may include a plurality of bonding pad patterns 214 that are spaced apart from one another in a second horizontal direction (Y direction). Each bonding pad pattern 214 may include a pair of first and second patterns 214a, 214b spaced apart in a first horizontal direction (X direction). Each of the pair of first and second patterns 214a, 214b may have a rectangular shape.

When forming the bonding wires 400 of FIG. 9, two bonding wires extending from the chip pads 210a, 210b of the first and second semiconductor chips 200a, 200b spaced apart in the first horizontal direction may be bonded to one second pattern 214b, and two bonding wires extending from the chip pads 210c, 210d of the third and fourth semiconductor chips 200c, 200d spaced apart in the first horizontal direction may be bonded to one first pattern 214a.

Referring to FIG. 15D, a bonding pad 212 may include a plurality of bonding pad patterns 214 spaced apart from one another in a second horizontal direction (Y direction). Each bonding pad pattern 214 may include a pair of first and second patterns 214a, 214b spaced apart from one another in a first horizontal direction (X direction). Each of the pair of first and second patterns 214a, 214b may have an oval shape. However, it will be understood that the shape of the bonding pad 212 is not limited thereto, and may have various shapes to provide a plane on which end portions of the bonding wires are bonded.

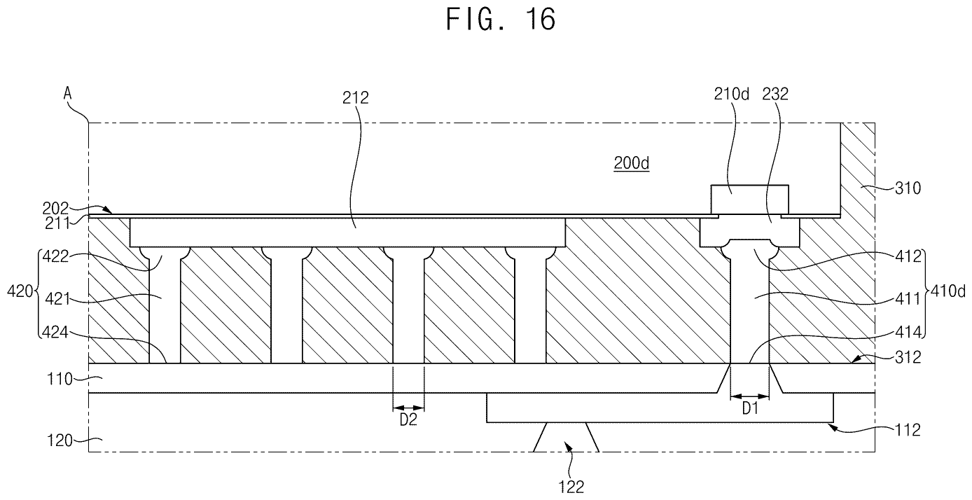

FIG. 16 is a cross-sectional view illustrating a chip pad of a fourth semiconductor chip of a semiconductor package according to example embodiments. FIG. 16 is an enlarged cross-sectional view illustrating portion ‘A’in FIG. 1.

Referring to FIG. 16, a pad pattern 232 may be provided on a chip pad 210d of a fourth semiconductor chip 200d, i.e., the lowest semiconductor chip closest to a redistribution wiring layer. The pad patterns 232 may be provided on the chip pads 210d of the fourth semiconductor chip 200d, respectively.

For example, an upper protective layer 211 may be provided on a front surface 202 of the fourth semiconductor chip 200d. The upper protective layer 211 may include an opening that exposes the chip pad 210d. The pad pattern 232 may be provided in the opening formed in the upper protective layer 211 and may be electrically connected to the chip pad 210d through the opening. The pad pattern 232 on the chip pad 210d may be spaced apart from a bonding pad 212 on the upper protective layer 211.

The pad pattern 232 may be formed with the bonding pad 212 by a wafer-level redistribution wiring process together. The pad pattern 232 may include a metal pattern on the chip pad 210d and at least one plating pattern layer formed on the metal pattern. The metal pattern may include a metal material such as copper (Cu). The plating pattern layer may include nickel (Ni), gold (Au), etc.

In example embodiments, a first conductive wire 410d may extend in a vertical direction (Z direction) from the pad pattern 232 on the chip pad 210d of the fourth semiconductor chip 200d within the sealing member 310 toward a first surface 312 of a sealing member 310. The first conductive wire 410d may include a first wire body 411 extending in the vertical direction, a first bonding end portion 412 provided at a first end portion of the first wire body 411 and bonded to the pad pattern 232, and a second bonding end portion 414 provided at a second end portion of the first wire body 411 opposite to the first end portion and bonded to a first redistribution wiring 112.

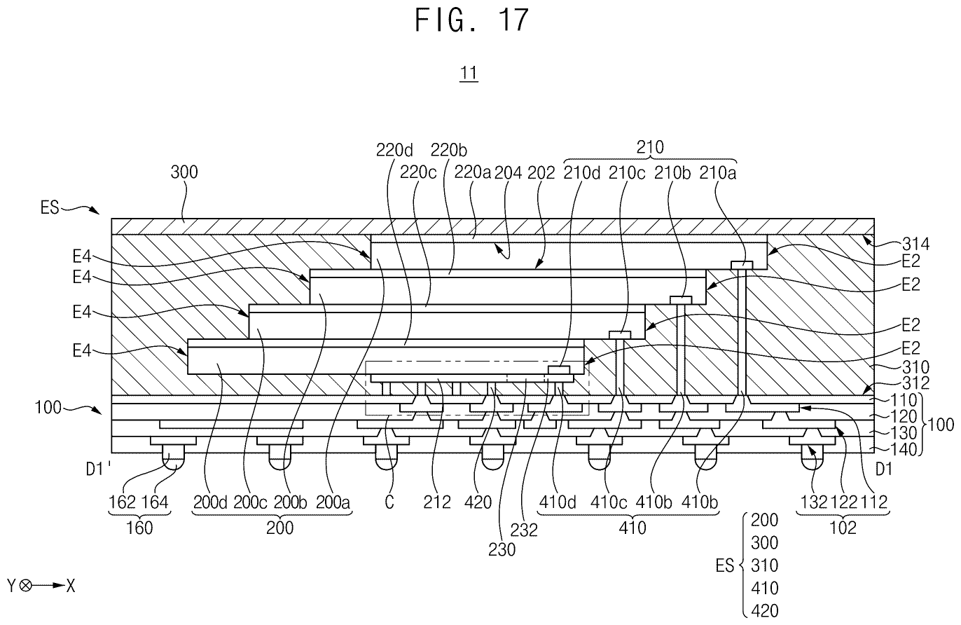

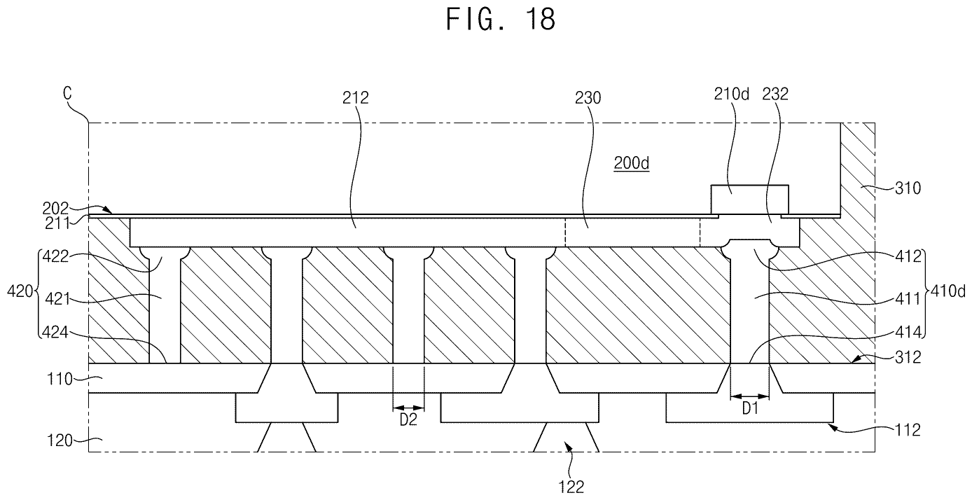

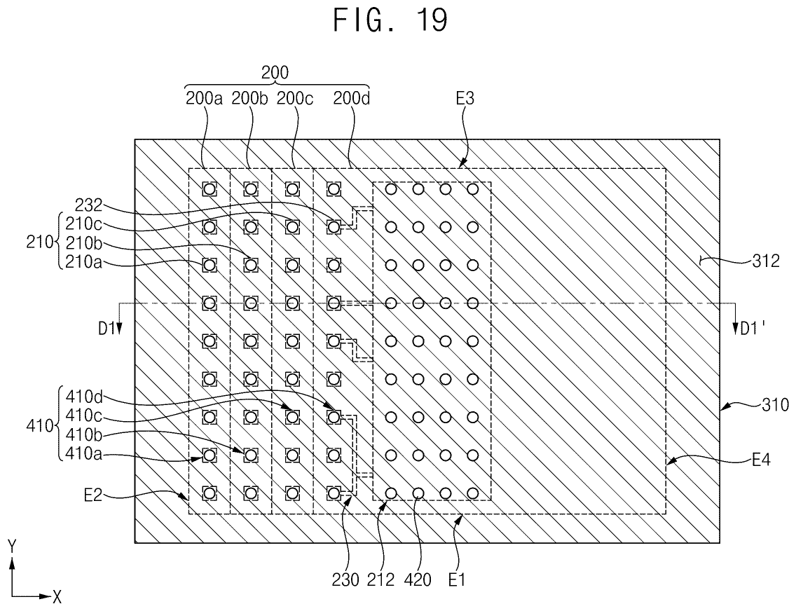

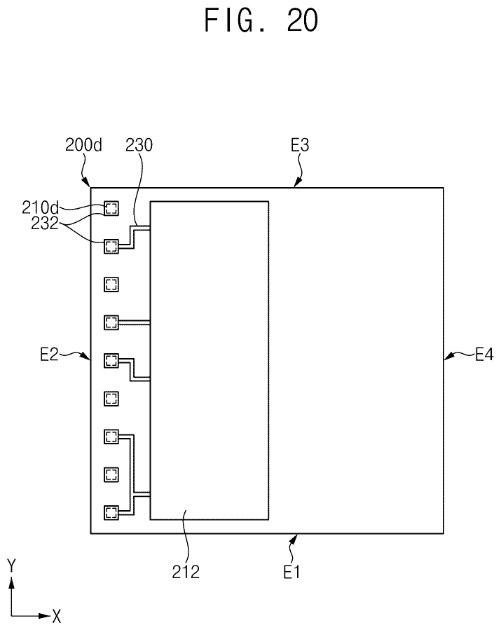

FIG. 17 is a cross-sectional view illustrating a semiconductor package in accordance with example embodiments. FIG. 18 is an enlarged cross-sectional view illustrating portion ‘C’ in FIG. 17. FIG. 19 is a bottom view illustrating a sealing member of the semiconductor package of FIG. 17. FIG. 20 is a plan view illustrating a front surface of a fourth semiconductor chip of FIG. 17. FIG. 17 includes a cross-section taken along the line D1-D1′ in FIG. 20.

The semiconductor package may be substantially the same as or similar to the semiconductor package described with reference to FIGS. 1 to 4, except for a connection relationship with a bonding pad. Thus, same reference numerals will be used to refer to the same or like elements and any further repetitive explanation concerning the above elements will be omitted.

Referring to FIGS. 17 to 20, a semiconductor package 11 may further include a connection wiring 230 that electrically connects a bonding pad 212 to at least one of chip pads 210d on a front surface 202 of a fourth semiconductor chip 200d, i.e., the lowest semiconductor chip closest to a redistribution wiring layer 100. In addition, the semiconductor package 10 may further include a pad pattern 232 that is provided on the chip pad 210d and is provide at an end portion of the connection wiring 230.

In example embodiments, the bonding pad 212 and the connection wiring 230 may be provided on an upper protective layer 211 formed on the front surface 202 of the fourth semiconductor chip 200d. The upper protective layer 211 may include an opening that exposes the chip pad 210d. The pad pattern 232 may be provided in the opening formed in the upper protective layer 211 and may be electrically connected to the chip pad 210d through the opening. The pad patterns 232 may be respectively disposed on the chip pads 210d.

The bonding pad 212 may be arranged to be spaced apart from the chip pads 210d in a first horizontal direction (X direction) from the pad patterns 232. The connection wiring 230 may extend from the pad pattern 232 to the bonding pad 212. Accordingly, at least one of the chip pads 210d may be electrically connected to the bonding pad 212 by the pad pattern 232 and the connection wiring 230. The connection wiring 230 may be a trace wiring extending on the upper protective layer 211. The bonding pad 212, the connection wiring 230, and the pad pattern 232 may be formed together by a wafer-level redistribution wiring process.

First conductive wires 410d may respectively extend in a vertical direction (Z direction) from the pad patterns 232 on the chip pads 210d of the fourth semiconductor chip 200d within a sealing member 310 to a first surface 312 of the sealing member 310. The first conductive wire 410d may include a first wire body 411 extending in the vertical direction, a first bonding end portion 412 provided at a first end portion of the first wire body 411 and bonded to the pad pattern 232, and a second bonding end portion 414 provided at a second end portion of the first wire body 411 opposite to the first end portion and bonded to a first redistribution wiring 112.

In example embodiments, second conductive wires 420 may respectively extend vertically from the first surface 312 of the sealing member 310 to the bonding pad 212. At least one of the second conductive wires 420 may be electrically connected to the redistribution wiring 102.

The at least one of the second conductive wires 420 may include a second wire body 421 extending in the vertical direction, a third bonding end portion 422 provided at a first end portion of the second wire body 421 and bonded to the bonding pad 212, and a fourth bonding end portion 424 provided at a second end portion of the second wire body 421 and bonded to the first redistribution wiring 112.

Since the at least one of the second conductive wires 420 is electrically connected to the redistribution wiring 102, at least one of the chip pads 210d may be electrically connected to the redistribution wiring 102 by the pad pattern 232, the connection wiring 230, the bonding pad 212, and the second conductive wire 420. The chip pad 210d electrically connected to the redistribution wiring 102 may be any one of a data chip pad for transmitting a data signal, a power chip pad for transmitting a power signal, and a ground chip pad for transmitting a ground signal. As the chip pad 210d and the bonding pad 212 are electrically connected to one another by the connection wiring 230, electrical signal characteristics such as signal integrity (SI) and power integrity (PI) can be improved.

Hereinafter, a method of manufacturing the semiconductor package of FIG. 17 will be described.

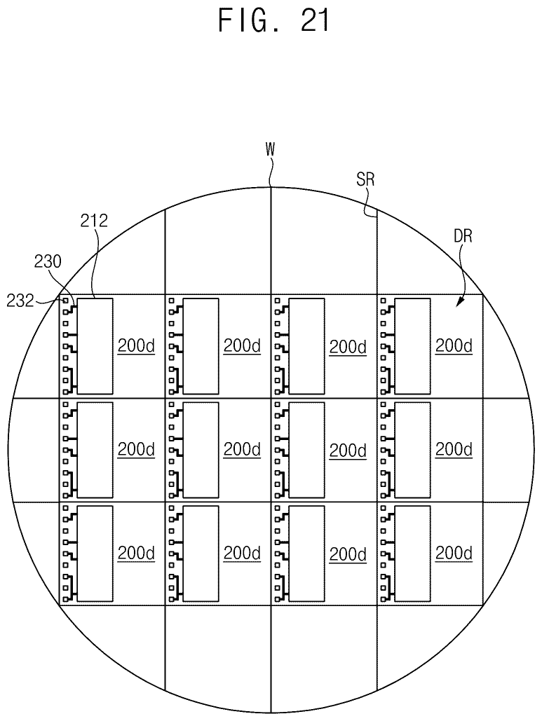

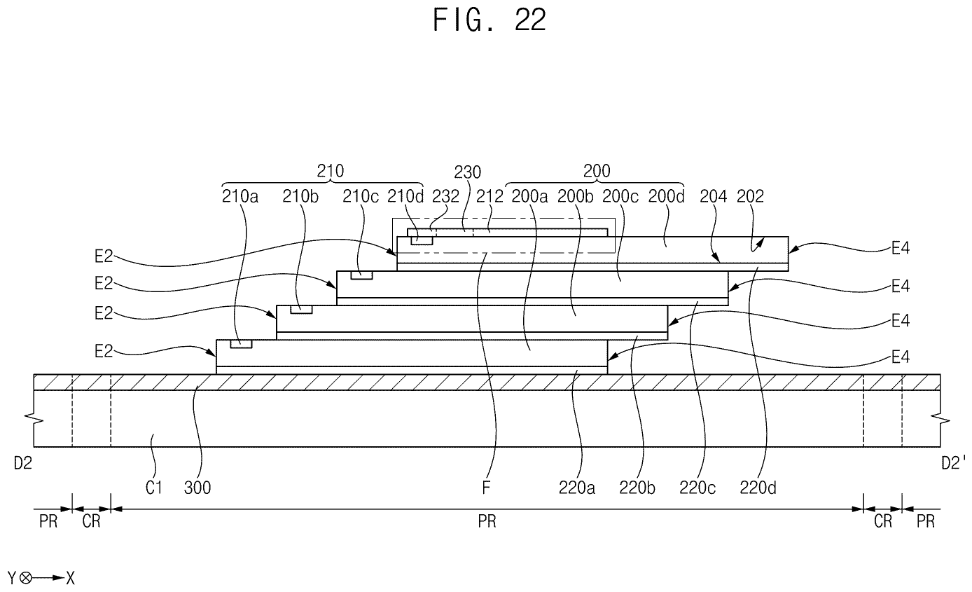

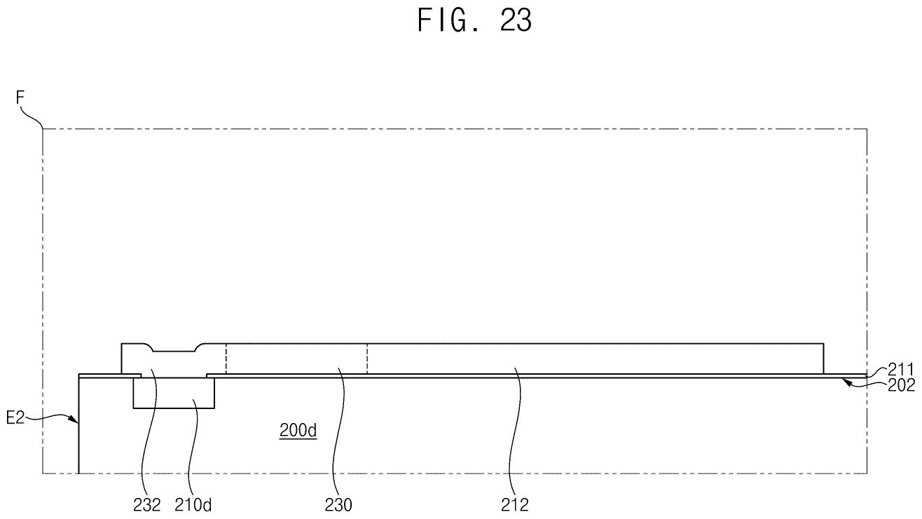

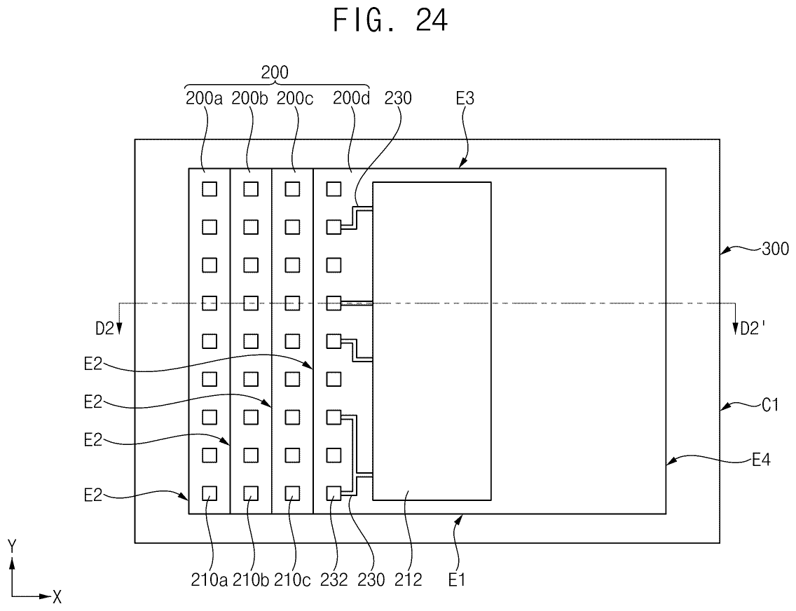

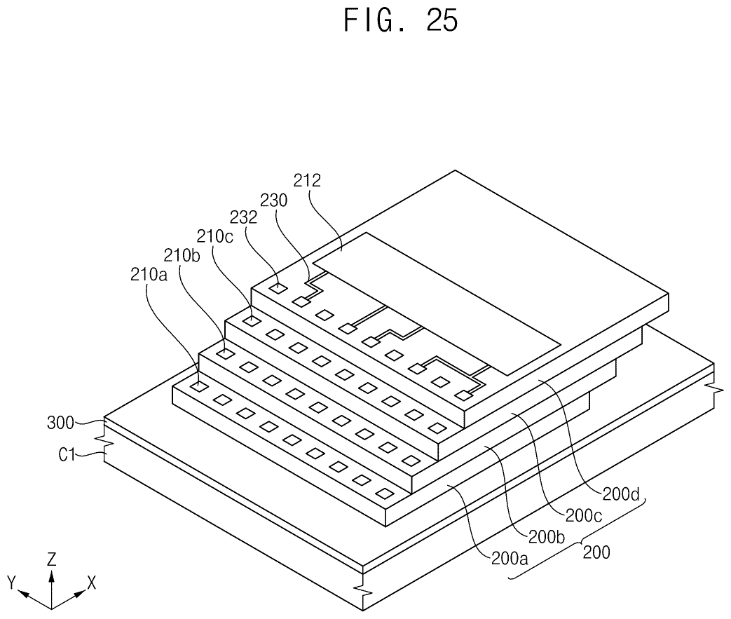

FIGS. 21 to 28 are views illustrating a method of manufacturing a semiconductor package in accordance with example embodiments. FIG. 21 is a plan view illustrating a wafer on which a plurality of fourth semiconductor chips are formed. FIGS. 22 and 26 to 28 are cross-sectional views illustrating a method of manufacturing a semiconductor package in accordance with example embodiments. FIG. 23 is an enlarged cross-sectional view illustrating portion ‘F’ in FIG. 22. FIG. 24 is a plan view of FIG. 22. FIG. 25 is a perspective view of FIG. 22. FIG. 22 is a cross-sectional view taken along the line D2-D2′ in FIG. 24.

Referring to FIGS. 21 to 25, a plurality of individual semiconductor chips 200 cut from a wafer may be prepared, a protective layer 300 may be formed on a carrier substrate C1, and the plurality of semiconductor chips 200 may be stacked on the protective layer 300.

As illustrated in FIGS. 21 and 23, in order to prepare fourth semiconductor chips 200d as the uppermost semiconductor chips among the plurality of semiconductor chips 200, a redistribution wiring process may be performed on a wafer W on which the fourth semiconductor chips 200d are formed, to form a bonding pads 212, connection wirings 230, and pad patterns 232 on a front surface of each of the fourth semiconductor chips 200d.

For example, a seed layer may be formed on the upper protective layer 211 formed on the front surface 202 of the fourth semiconductor chip 200d, a photoresist pattern having openings that expose a bonding pad region, a connection wiring region and a pad pattern region may be formed, and a plating process may be performed to form the bonding pad 212, the connection wiring 230 and the pad pattern 232 in the openings. Then, the photoresist pattern may be removed by a stripping process.

The pad pattern 232 may be provided in the opening formed in the upper protective layer 211 and may be electrically connected to a chip pad 210d through the opening. The pad pattern 232 on the chip pad 210d may be spaced apart from the bonding pad 212 on the upper protective layer 211. The connection wiring 230 may extend from the pad pattern 232 to the bonding pad 212. Accordingly, at least one of the chip pads 210d may be electrically connected to the bonding pad 212 by the pad pattern 232 and the connection wiring 230. The chip pad 210d electrically connected to the bonding pad 212 may be any one of a data chip pad for transmitting a data signal, a power chip pad for transmitting a power signal, and a ground chip pad for transmitting a ground signal.

The bonding pad 212, the connection wiring 230, and the pad patterns 232 may be formed integrally. Each of the bonding pad 212, the connection wiring 230, and the pad patterns 232 may include a metal pattern and at least one plating pattern layer formed on the metal pattern. The metal pattern may include a metal material such as copper (Cu). The plating pattern layer may include nickel (Ni), gold (Au), etc.

The wafer W may include die regions DR on which the fourth semiconductor chips are formed and a cutting region CR surrounding the die regions DR. After forming the bonding pad 212, the connection wiring 230, and the pad patterns 232 on each of the fourth semiconductor chips, the wafer W may be cut along the cutting region CR that divides the die regions DR to be individualized into the fourth semiconductor chips 200d.

Then, as illustrated in FIGS. 22 to 25, processes the same as or similar to the processes described with reference to FIGS. 5 to 8 may be performed to form a protective layer 300 on a carrier substrate C1, and a plurality of semiconductor chips 200 may be stacked on the protective layer 300.

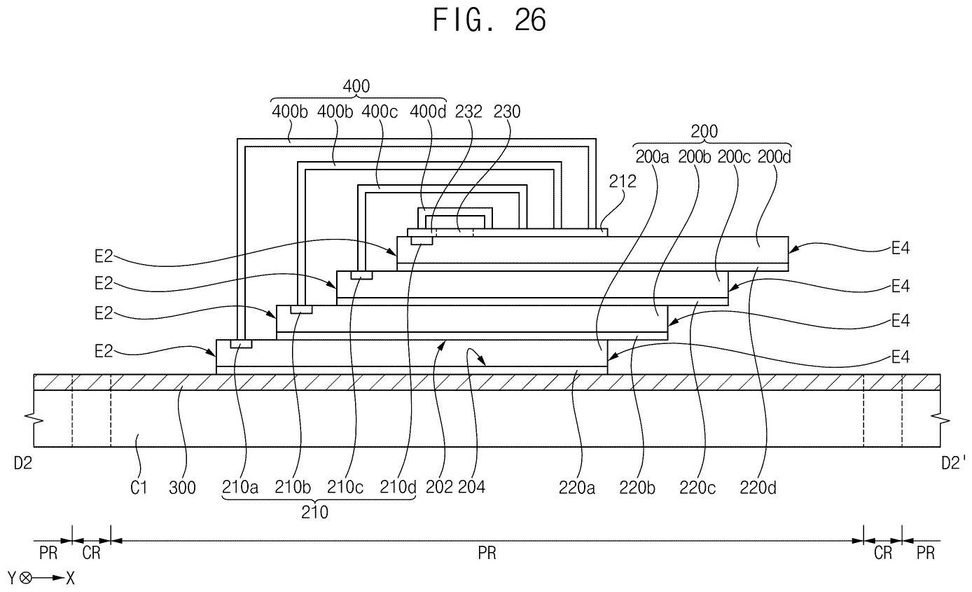

Referring to FIG. 26, processes the same as or similar to the processes described with reference to FIGS. 8 and 9 may be performed using a wire bonding apparatus to form a plurality of bonding wires 400 that connect chip pads 210 of the semiconductor chips 200 to the bonding pad 212 on the fourth semiconductor chip 200d.

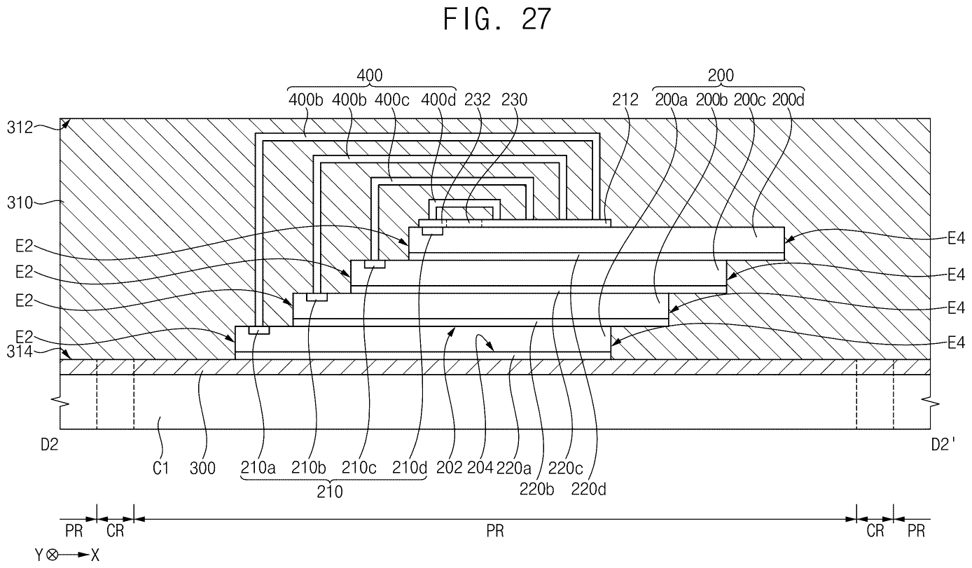

Referring to FIG. 27, processes the same as or similar to the processes described with reference to FIG. 10 may be performed to form a sealing member 310 that covers the plurality of semiconductor chips 200 and the plurality of bonding wires 400 on the protective layer 300 on the carrier substrate C1.

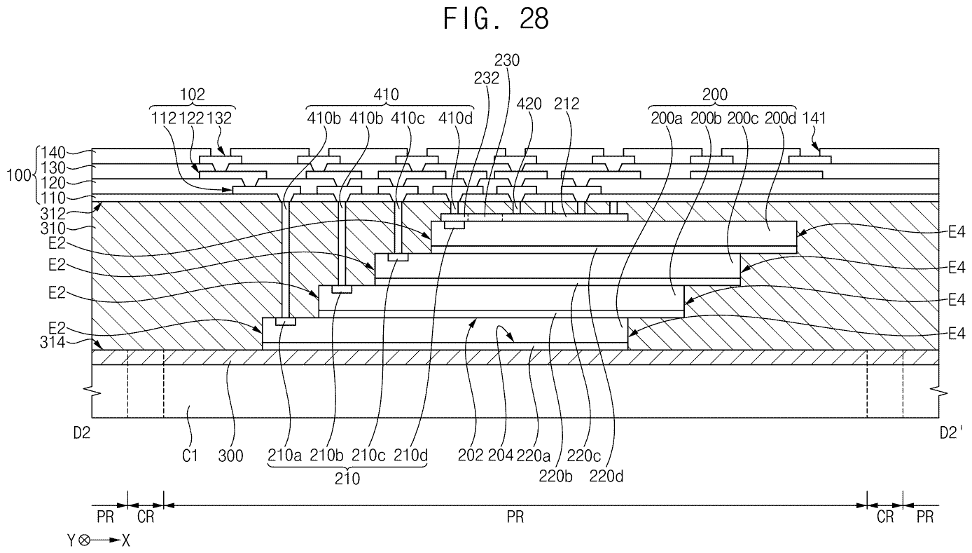

Referring to FIG. 28, processes the same as or similar to the processes described with reference to FIGS. 11 and 12 may be performed to remove an upper portion of the sealing member 310 to have a desired height, and then processes the same as or similar to the processes described with reference to FIGS. 13 and 14 may be performed to form a redistribution wiring layer 100 on a first surface 312 of the sealing member 310.

As the upper portion of the sealing member 310 is removed, the plurality of bonding wires 400 may be partially removed to form first conductive wires 410 extending vertically from the chip pads 210 of the semiconductor chips 200 and second conductive wires 420 extending vertically from the bonding pad 212.

By removing a portion of one bonding wire 400, one first conductive wire 410 and one second conductive wire 420 may be formed. Accordingly, the number of the first conductive wires 410 may be the same as the number of the second conductive wires 420.

Each of the first conductive wires 410 may include a first wire body extending in a vertical direction, a first bonding end portion provided at a first end portion of the first wire body and bonded to the pad pattern 232, and a second bonding end portion provided at a second end portion of the first wire body. Each of the second conductive wires 420 may include a second wire body extending in the vertical direction, a third bonding end portion provided at a first end portion of the second wire body and bonded to the bonding pad 212, and a fourth bonding end portion provided at a second end portion of the second wire body. The second bonding end portion of each of the first conductive wires 410 and the fourth bonding end portion of each of the second conductive wires 420 may be exposed from the first surface 312 of the sealing member 310.

The redistribution wiring layer 100 having redistribution wirings 102 electrically connected to the first conductive wires 410 may be formed on the first surface 312 of the sealing member 310. At this time, at least one of the second conductive wires 420 may be electrically connected to the redistribution wirings 102.

For example, after forming a first lower insulating layer 110 on the first surface 312 of the sealing member 310, the first lower insulating layer 110 may be patterned to form first openings. The first openings may expose end portions of the first conductive wires 410, i.e., the second bonding end portions, and end portions of the second conductive wires 420, i.e., the fourth bonding end portions, respectively.

Then, a seed layer may be formed on the exposed end portions of the first conductive wires 410 and the end portions of the second conductive wires 420 and within the first openings, and then the seed layer may be patterned and an electroplating process may be performed to form first redistribution wirings 112. Accordingly, at least one of the first redistribution wirings 112 may be electrically connected to the first conductive wires 410 and the second conductive wires 420 through the first openings.

Accordingly, the redistribution wiring layer 100 having the first redistribution wirings 102 as a front redistribution layer FRDL may be formed on the sealing member 310. The redistribution wiring layer 100 may include stacked first to fourth lower insulating layers 110, 120, 130, 140, and redistribution wirings 102 in the first to fourth lower insulating layers 110, 120, 130, 140. The redistribution wirings 102 may include first, second, and third lower redistribution wirings 112, 122, 132.

Then, external connection members 160 electrically connected to the redistribution wirings 102 may be formed on the redistribution wiring layer 100, and the redistribution wiring layer 100, the sealing member 310, and the protective layer 300 may be cut along the cutting region CR, to complete a semiconductor package 11 of FIG. 17.

Since at least one of the second conductive wires 420 is electrically connected to the redistribution wiring 102, at least one of the chip pads 210d may be electrically connected to the redistribution wiring 102 by the pad pattern 232, the connection wiring 230, the bonding pad 212, and the second conductive wire 420. The chip pad 210d electrically connected to the redistribution wiring 102 may be any one of a data chip pad for transmitting a data signal, a power chip pad for transmitting a power signal, and a ground chip pad for transmitting a ground signal. Since the chip pad 210d and the bonding pad 212 are electrically connected to one another by the connection wiring 230, electrical signal characteristics such as signal integrity (SI) and power integrity (PI) can be improved.

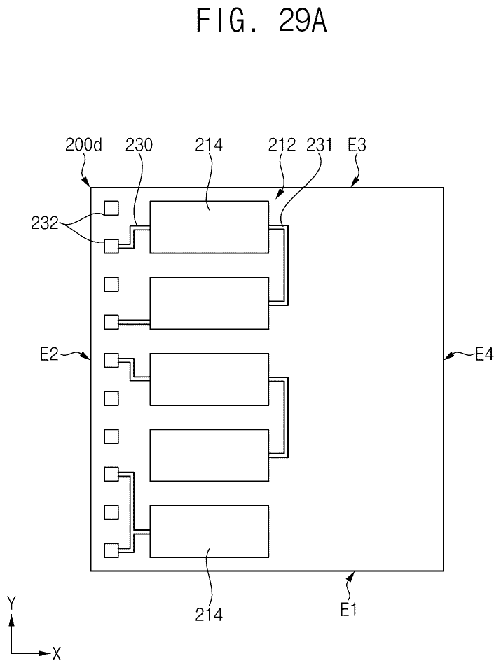

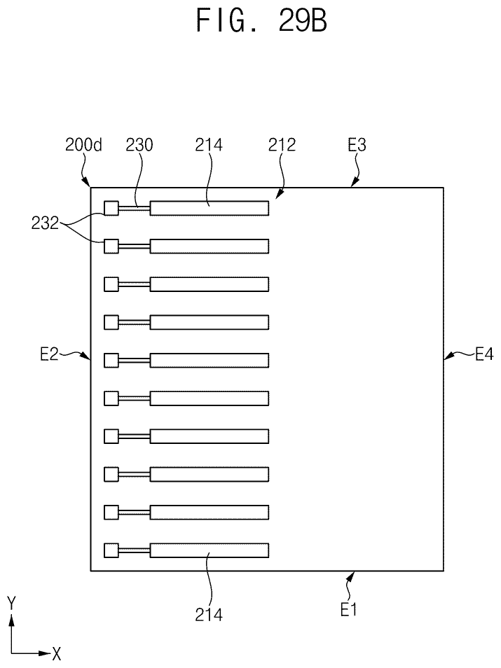

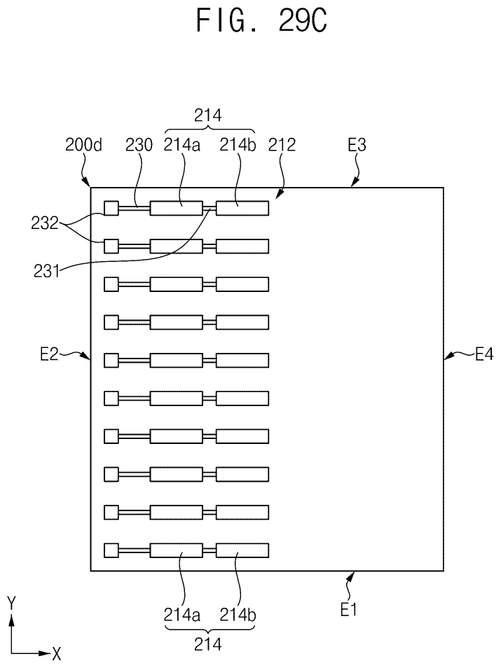

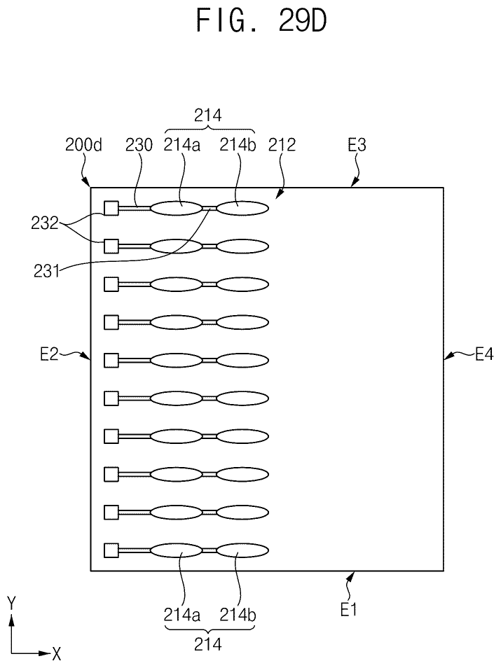

FIGS. 29A to 29D are plan views illustrating bonding pads and connection wirings having various shapes.

Referring to FIG. 29A, a bonding pad 212 provided on a front surface 202 of a fourth semiconductor chip 400d may include a plurality of bonding pad patterns 214 that are spaced apart from one another in a second horizontal direction (Y direction). Each bonding pad pattern 214 may extend in a first horizontal direction (X direction).

A width (length) of the bonding pad pattern 214 in the second direction may be determined in consideration of the number of bonding wires bonded to the bonding pad pattern 214.

For example, when forming the bonding wires 400 of FIG. 26, eight bonding wires spaced apart in the second horizontal direction and extending from two adjacent chip pads 210 may be bonded to one bonding pad pattern 214. Additionally, at least one of the bonding pad patterns 214 may be electrically connected to a pad pattern 232 on the chip pad by a connection wiring 230. The bonding pad patterns 214 may be electrically connected to one another by a second connection wiring 231.

Referring to FIG. 29B, a bonding pad 212 may include a plurality of bonding pad patterns 214 that are spaced apart from one another in a second horizontal direction (Y direction). Each bonding pad pattern 214 may extend in a first horizontal direction (X direction).

When forming the bonding wires 400 of FIG. 26, four bonding wires extending from the chip pads 210a, 210b, 210c, 210d of the first to fourth semiconductor chips 200a, 200b, 200c, 200d spaced apart from one another in the first horizontal direction may be bonded to one bonding pad pattern 214.

In addition, the bonding pad patterns 214 may be electrically connected to pad patterns 232 by connection wirings 230, respectively.

Referring to FIG. 29C, a bonding pad 212 may include a plurality of bonding pad patterns 214 that are spaced apart from one another in a second horizontal direction (Y direction). Each bonding pad pattern 214 may include a pair of first and second patterns 214a, 214b spaced apart in a first horizontal direction (X direction). Each of the pair of first and second patterns 214a, 214b may have a rectangular shape.

When forming the bonding wires 400 of FIG. 26, two bonding wires extending from the chip pads 210a, 210b of the first and second semiconductor chips 200a, 200b spaced apart in the first horizontal direction may be bonded to one second pattern 214b, and two bonding wires extending from the chip pads 210c, 210d of the third and fourth semiconductor chips 200c, 200d spaced apart in the first horizontal direction may be bonded to one first pattern 214a.

In addition, among the bonding pad patterns 214, the first patterns 214a may be electrically connected to pad patterns 232 via connection wirings 230, respectively. The pair of first and second patterns 214a, 214b may be electrically connected to one another by a second connection wiring 231.

Referring to FIG. 29D, a bonding pad 212 may include a plurality of bonding pad patterns 214 that spaced apart from one another in a second horizontal direction (Y direction). Each bonding pad pattern 214 may include a pair of first and second patterns 214a, 214b spaced apart in a first horizontal direction (X direction). Each of the pair of first and second patterns 214a, 214b may have an oval shape.

However, it will be understood that the shape of the bonding pad 212 is not limited thereto, and may have various shapes to provide a plane on which end portions of the bonding wires are bonded.

In addition, the first patterns 214a of the bonding pad patterns 214 may be electrically connected to pad patterns 232 via connection wirings 230, respectively. The pair of first and second patterns 214a, 214b may be electrically connected to one another by a second connection wiring 231.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a redistribution wiring layer having redistribution wirings;
a sealing member provided on the redistribution wiring layer and having a first surface in contact with the redistribution wiring layer and a second surface opposite to the first surface;
a plurality of semiconductor chips sequentially stacked on one another within the sealing member and arranged such that a front surface on which chip pads of each of the semiconductor chips are formed faces the redistribution wiring layer;
a bonding pad spaced apart from the chip pads on the front surface of the lowest semiconductor chip of the plurality of semiconductor chips that is closest to the first surface of the sealing member;
first conductive wires extending substantially vertically from the first surface of the sealing member to the chip pads of the semiconductor chips and electrically connected to the redistribution wirings, respectively; and
second conductive wires extending substantially vertically from the first surface of the sealing member to the bonding pad, respectively.

2. The semiconductor package of claim 1, wherein the chip pads of each of the plurality of semiconductor chips are spaced apart from one another in a first direction, and the bonding pad is on the front surface to be spaced apart from the chip pads of the lowest semiconductor chip in a second direction perpendicular to the first direction.

3. The semiconductor package of claim 1, wherein a number of the first conductive wires is equal to a number of the second conductive wires.

4. The semiconductor package of claim 1, wherein a diameter of each of the first conductive wires is as approximately equal to a diameter of each of the second conductive wires.

5. The semiconductor package of claim 1, wherein at least one of the second conductive wires is electrically connected to the redistribution wiring.

6. The semiconductor package of claim 1, wherein each of the second conductive wires comprises:
a wire body extending in a substantially vertical direction;
a first bonding end portion provided at a first end portion of the wire body and exposed from the first surface of the sealing member; and
a second bonding end portion provided at a second end portion of the wire body and bonded to the bonding pad.

7. The semiconductor package of claim 6, wherein the second conductive wires comprise copper (Cu), gold (Au), or aluminum (Al).

8. The semiconductor package of claim 1, further comprising:
a protective layer disposed on the second surface of the sealing member.

9. The semiconductor package of claim 8, wherein:
the plurality of semiconductor chips include first, second, third, and fourth semiconductor chips that are stacked in a cascade structure from a lower surface of the protective layer, the fourth semiconductor chip being the lowest semiconductor chip,
each of the first, second, and third semiconductor chips includes an overhang portion protruding from one side of each of the underlying second, third, and fourth semiconductor chips, and
the chip pads of each of the first, second, and third semiconductor chips are provided on a lower surface of the overhang portion.

10. The semiconductor package of claim 1, further comprising
a connection wiring electrically connecting the bonding pad to at least one of the chip pads on the front surface of the lowest semiconductor chip.

11. A semiconductor package, comprising:
a redistribution wiring layer having redistribution wirings;
an encapsulation structure provided on the redistribution wiring layer; and
outer connection members arranged on an outer surface of the redistribution wiring layer and electrically connected to the redistribution wirings,
wherein the encapsulation structure includes:
a sealing member having a first surface in contact with the redistribution wiring layer and a second surface opposite to the first surface;
a plurality of semiconductor chips sequentially stacked within the sealing member such that a front surface on which chip pads are formed faces the redistribution wiring layer, the lowest semiconductor chip of the plurality of semiconductor chips closest to the first surface of the sealing member having a bonding pad spaced apart from the chip pads;
first conductive wires extending substantially vertically from the first surface of the sealing member to the chip pads of the semiconductor chips and electrically connected to the redistribution wirings, respectively; and
second conductive wires extending substantially vertically from the first surface of the sealing member to the bonding pad of the lowest semiconductor chip, respectively,
wherein the bonding pad is provided on the front surface of the lowest semiconductor chip.

12. The semiconductor package of claim 11, wherein a number of the first conductive wires is equal to a number of the second conductive wires.

13. The semiconductor package of claim 11, wherein a diameter of each of the first conductive wires is as approximately equal to a diameter of each of the second conductive wires.

14. The semiconductor package of claim 13, wherein each of the first conductive wires and the second conductive wires has a diameter within a range of 13 μm to 40 μm.

15. The semiconductor package of claim 11, wherein the encapsulation structure further includes a connection wiring that electrically connects the bonding pad to at least one of the chip pads of the lowest semiconductor chip.

16. The semiconductor package of claim 15, wherein at least one of the second conductive wires is electrically connected to the redistribution wiring.

17. The semiconductor package of claim 11, wherein the second conductive wires comprises copper (Cu), gold (Au), or aluminum (Al).

18. The semiconductor package of claim 11, wherein the encapsulation structure further includes a protective layer disposed on the second surface of the sealing member.

19. The semiconductor package of claim 18, wherein:
the plurality of semiconductor chips include first, second, third, and fourth semiconductor chips that are stacked in a cascade structure from a lower surface of the protective layer, the fourth semiconductor chip being the lowest semiconductor chip,
each of the first, second, and third semiconductor chips includes an overhang portion protruding from one side of each of the underlying second, third, and fourth semiconductor chips, and
the chip pads of each of the first, second, and third semiconductor chips are provided on a lower surface of the overhang portion.

20. A semiconductor package, comprising:
a redistribution wiring layer having redistribution wirings;
a sealing member provided on the redistribution wiring layer and having a first surface in contact with the redistribution wiring layer and a second surface opposite to the first surface;
a plurality of semiconductor chips sequentially stacked on one another within the sealing member and arranged such that a front surface on which chip pads of each of the semiconductor chips are formed faces the redistribution wiring layer;
a bonding pad spaced apart from the chip pads on the front surface of the lowest semiconductor chip of the plurality of semiconductor chips that is closest to the first surface of the sealing member;
a connection wiring electrically connecting the bonding pad to at least one of the chip pads on the front surface of the lowest semiconductor chip;
first conductive wires extending substantially vertically from the first surface of the sealing member to the chip pads of the semiconductor chips and electrically connected to the redistribution wirings, respectively; and
second conductive wires extending substantially vertically from the first surface of the sealing member to the bonding pad, respectively,
wherein at least one of the second conductive wires is electrically connected to the redistribution wiring.
